(19) United States
(12) Patent Application Publication
(10) Pub. No.: US 2026/0255804 A1
(43) Pub. Date: Aug. 27, 2026

(54) ELECTRONIC APPARATUS

(71) Applicant: Samsung Display Co., Ltd., Yongin-Si (KR)

(72) Inventors: HANBIT KIM, Yongin-si (KR); MEEJAE KANG, Yongin-si (KR); DOO-NA KIM, Yongin-si (KR); JIYEONG SHIN, Yongin-si (KR); KISEOK CHOI, Yongin-si (KR); SANGGUN CHOI, Yongin-si (KR)

(21) Appl. No.: 19/368,112

(22) Filed: Oct. 24, 2025

(30) Foreign Application Priority Data
Feb. 24, 2025 (KR) 10-2025-0023436

(51) Int. Cl. H10K 59/121; H10K 59/12; H10K 59/131; H10K 59/40

(52) U.S. Cl. CPC H10K 59/1216; H10K 59/1201; H10K 59/1213; H10K 59/131; H10K 59/40

(57) ABSTRACT

An electronic apparatus includes a base layer, a gate line extending in a first direction, a data line insulated from the gate line and extending in a second direction, and a pixel including a pixel driver connected to the gate line and the data line and a light-emitting element connected to the pixel driver. The light-emitting element includes an anode, a cathode, and a light-emitting layer, and the pixel driver includes a first transistor including a first semiconductor pattern and a first gate electrode, a second transistor including a second semiconductor pattern connected to the data line and spaced apart from the first semiconductor pattern and a second gate electrode, a first capacitor connected between the second transistor and the data line, and a second capacitor connected to the first transistor. The first semiconductor pattern is disposed between the first capacitor and the second capacitor in a cross-sectional view.

### CROSS-REFERENCE TO RELATED APPLICATIONS

This application claims priority under 35 U.S.C. § 119 to Korean Patent Application No. 10-2025-0023436, filed on Feb. 24, 2025, the entire contents of which are hereby incorporated by reference.

### BACKGROUND

The present disclosure herein relates to an electronic apparatus having improved resolution.

Display devices such as televisions, monitors, smartphones, and tablets that provide images to users include a display panel that displays images. Various display panels, such as a liquid crystal display panel, an organic light-emitting display panel, an electro wetting display panel, and an electrophoretic display panel, have been developed.

A display panel includes a plurality of pixels configured to generate images. The display panel includes a gate driver configured to apply gate signals to the pixels, and a data driver configured to apply data voltages to the pixels. The pixels receive the data voltages in response to the gate signals and emit light corresponding to the data voltages to generate images. Each of the pixels includes a light-emitting element and a plurality of transistors connected to the light-emitting element.

The light-emitting element is driven or controlled by the transistors and generates light. Among the transistors, a driving transistor is connected to the light-emitting element through a connection electrode. The connection electrode is connected to the driving transistor through a contact hole formed in an insulating layer. Since the area occupied by the contact hole in each pixel is limited, technology development is required for precisely manufacturing the contact hole.

### SUMMARY

The present disclosure provides an electronic apparatus with improved resolution by distributing two capacitors respectively on the upper and lower sides of an active layer of a transistor in each pixel to secure the area of the capacitors and to control the depth of a contact hole.

According to an embodiment of the inventive concept, an electronic apparatus includes a base layer, a gate line disposed on the base layer and extending in a first direction, a data line insulated from the gate line and extending in a second direction crossing the first direction, and a pixel including a pixel driver connected to the gate line and the data line and a light-emitting element disposed on the pixel driver and connected to the pixel driver. The light-emitting element includes an anode, a cathode disposed on the anode, and a light-emitting layer disposed between the anode and the cathode, and the pixel driver includes a first transistor including a first semiconductor pattern and a first gate electrode overlapping the first semiconductor pattern, a second transistor including a second semiconductor pattern connected to the data line and spaced apart from the first semiconductor pattern and a second gate electrode overlapping the second semiconductor pattern, a first capacitor connected between the second transistor and the data line, and a second capacitor connected to the first transistor. The first capacitor is disposed below the first semiconductor pattern, and the second capacitor is disposed above the first semiconductor pattern.

In an embodiment, the first capacitor may include a first lower capacitor electrode and a second lower capacitor electrode disposed on the first lower capacitor electrode. An area occupied by each of the first and second lower capacitor electrodes may be larger than an area occupied by the anode in a plan view.

In an embodiment, the first lower capacitor electrode may have a shape integrated with the data line.

In an embodiment, the second lower capacitor electrode may have a shape integrated with the data line.

In an embodiment, a ratio between the area occupied by each of the first and second lower capacitor electrodes and the area occupied by the anode may be 1.4 or more.

In an embodiment, the electronic apparatus may further include a lower conductive pattern disposed between the first capacitor and the first transistor, and a buffer layer disposed on the lower conductive pattern. The lower conductive pattern may overlap the first semiconductor pattern.

In an embodiment, a short-range surface roughness of the buffer layer may be less than 10 nm, and a long-range surface roughness of the buffer layer may be less than 200 nm.

In an embodiment, the first transistor may include a silicon semiconductor, and the second transistor may include an oxide semiconductor.

In an embodiment, a spacing distance between the first semiconductor pattern and the anode in a third direction crossing the first direction and the second direction may be 1.5 μm or less.

In an embodiment, the electronic apparatus may further include an upper electrode connecting the first capacitor to the second transistor. The upper electrode may be disposed on the first capacitor and the second transistor.

In an embodiment, the upper electrode may include a same material as at least one of electrodes of the second capacitor.

According to an embodiment of the inventive concept, an electronic apparatus includes a base layer, a gate line disposed on the base layer and extending in a first direction, a data line including a line portion insulated from the gate line and extending in a second direction crossing the first direction and a protruding portion protruding from the line portion, and a pixel including a pixel driver connected to the gate line and the data line and a light-emitting element disposed on the pixel driver and connected to the pixel driver. The light-emitting element includes an anode, a cathode disposed on the anode, and a light-emitting layer disposed between the anode and the cathode, and the pixel driver includes a first transistor including a first semiconductor pattern and a first gate electrode overlapping the first semiconductor pattern, a second transistor including a second semiconductor pattern connected to the data line and spaced apart from the first semiconductor pattern and a second gate electrode overlapping the second semiconductor pattern, and a capacitor electrode disposed below the first semiconductor pattern and overlapping the protruding portion of the data line in a plan view. The protruding portion of the data line overlaps the anode in the plan view.

In an embodiment, an area occupied by each of the protruding portion and the capacitor electrode may be larger than an area occupied by the anode.

In an embodiment, the capacitor electrode may be disposed above the protruding portion.

In an embodiment, the capacitor electrode may be disposed below the protruding portion.

In an embodiment, the electronic apparatus may further include a lower conductive pattern disposed between the capacitor electrode and the first transistor, and a buffer layer disposed on the lower conductive pattern. The lower conductive pattern may overlap the first semiconductor pattern.

In an embodiment, the first transistor may include a silicon semiconductor, and the second transistor may include an oxide semiconductor.

In an embodiment, the electronic apparatus may further include an upper electrode connecting the capacitor electrode to the second transistor. The upper electrode may be disposed on the capacitor electrode and the second transistor.

According to an embodiment of the inventive concept, an electronic apparatus includes a display module configured to display an image, and a processor configured to provide image data to the display module. The display module includes a base layer, a gate line disposed on the base layer and extending in a first direction, a data line insulated from the gate line and extending in a second direction crossing the first direction, and a pixel including a pixel driver connected to the gate line and the data line and a light-emitting element disposed on the pixel driver and connected to the pixel driver. The light-emitting element includes an anode, a cathode disposed on the anode, and a light-emitting layer disposed between the anode and the cathode, and the pixel driver includes a first transistor including a first semiconductor pattern and a first gate electrode overlapping the first semiconductor pattern, a second transistor including a second semiconductor pattern connected to the data line and spaced apart from the first semiconductor pattern and a second gate electrode overlapping the second semiconductor pattern, a first capacitor connected between the second transistor and the data line, and a second capacitor connected to the first transistor. The first capacitor is disposed below the first semiconductor pattern, and the second capacitor is disposed above the first semiconductor pattern.

In an embodiment, the first capacitor may include a first lower capacitor electrode and a second lower capacitor electrode disposed on the first lower capacitor electrode. An area occupied by each of the first and second lower capacitor electrodes may be larger than an area occupied by the anode in a plan view.

### BRIEF DESCRIPTION OF THE FIGURES

The accompanying drawings are included to provide a further understanding of the inventive concept, and illustrate embodiments of the inventive concept together with the description to explain features of the inventive concept.

FIG. 1A is a perspective view of an electronic apparatus according to an embodiment of the inventive concept.

FIG. 1B is a block diagram of the electronic apparatus according to an embodiment of the inventive concept.

FIG. 2A and FIG. 2B are perspective views of an electronic apparatus according to an embodiment of the inventive concept.

FIG. 3 illustrates a cross section of the electronic apparatus illustrated in FIG. 1A.

FIG. 4 illustrates a cross section of a display panel illustrated in FIG. 3.

FIG. 5 is a plan view of the display panel according to an embodiment of the inventive concept.

FIG. 6 illustrates an equivalent circuit of a pixel included in the display panel illustrated in FIG. 5.

FIG. 7 is a timing diagram of signals for operating the pixel illustrated in FIG. 6.

FIG. 8 is a cross-sectional view of the display panel taken along a line I-I′ of FIG. 5.

FIG. 9 is a cross-sectional view of a display panel taken along a line I-I′ of FIG. 5.

FIGS. 10A to 10N are plan views illustrating a portion of the display panel according to an embodiment of the inventive concept.

FIGS. 11A to 11J are cross-sectional views illustrating some steps of a method of manufacturing the display panel according to an embodiment of the inventive concept.

FIGS. 12A to 12C are cross-sectional views illustrating some steps of the method of manufacturing the display panel according to an embodiment of the inventive concept.

### DETAILED DESCRIPTION

In this specification, it will be understood that when an element (or region, layer, portion, etc.) is referred to as being “on”, “connected to” or “coupled to” another element, it can be directly on, connected or coupled to the other element, or indirectly on, connected to or coupled to the other element with an intervening element disposed therebetween.

Like reference numerals refer to like elements throughout this specification. In addition, in the drawings, the thicknesses, ratios, and dimensions of elements are exaggerated for effective description of the technical features of the inventive concept. As used herein, the term “and/or” includes any and all combinations that the associated configurations can define.

It will be understood that, although the terms “first”, “second”, etc. may be used herein to describe various elements, these elements should not be limited by these terms. These terms are only used to distinguish one element from another element. For example, a first element could be referred to as a second element without departing from the scope of the inventive concept. Similarly, the second element may also be referred to as the first element. The terms of a singular form include plural forms unless the context clearly indicates otherwise.

In addition, terms, such as “below”, “lower”, “above”, “upper” or the like, are used herein for ease of description to describe the spatial relation between one element to another element(s) as illustrated in the figures. The above terms are relative concepts and are described based on the directions indicated in the drawings.

It will be understood that the terms “comprise”, “include”, “have”, or its variation such as “comprising”, “including” or “having”, when used in this specification, specify the presence of stated features, integers, steps, operations, elements, components and/or groups thereof, but do not preclude the presence or addition of one or more other features, integers, steps, operations, elements, components, and/or groups thereof.

Unless defined otherwise, all terms (including technical and scientific terms) used herein have the same meaning as commonly understood by one of ordinary skill in the art to which the inventive concept pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be described with reference to the accompanying drawings.

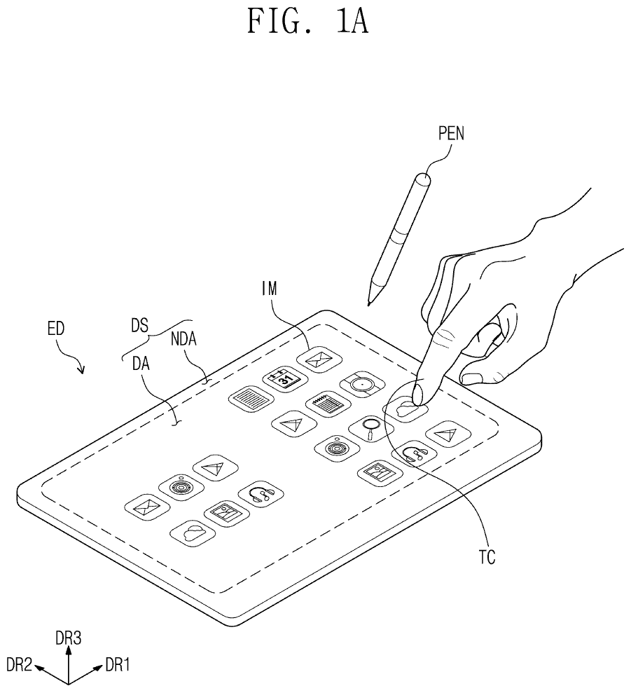

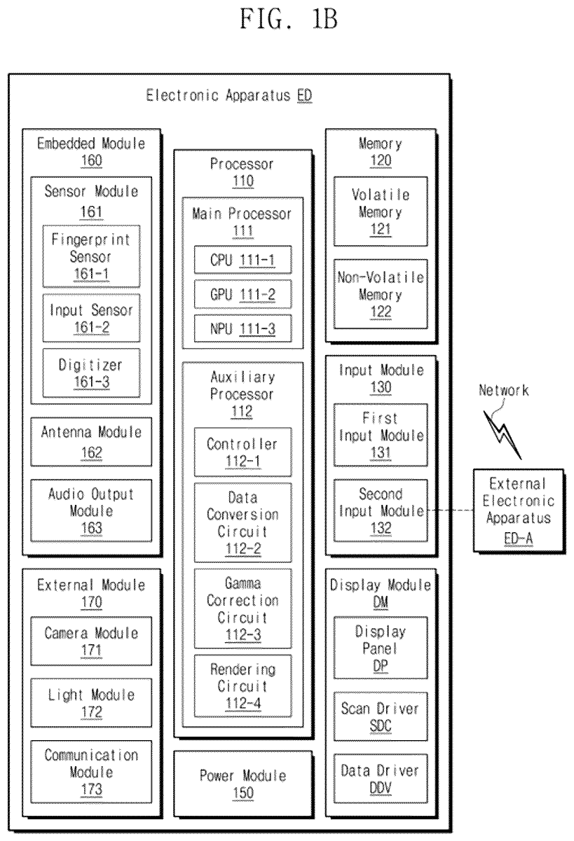

FIG. 1A is a perspective view of an electronic apparatus according to an embodiment of the inventive concept. FIG. 1B is a block diagram of the electronic apparatus according to an embodiment of the inventive concept.

Referring to FIG. 1A, the electronic apparatus ED may include long sides extending parallel to a first direction DR1 and short sides extending parallel to a second direction DR2 crossing the first direction DR1. However, this is illustrated as an example, and the electronic apparatus ED may include sides having the same length as each other in both the first direction DR1 and the second direction DR2 and is not limited to an embodiment illustrated in FIG. 1A.

Hereinafter, a direction substantially perpendicular to a plane defined by the first direction DR1 and the second direction DR2 is referred to as a third direction DR3. In addition, in this specification, the meaning of when viewed on a plane, or the term “in a plan view” is defined as a state viewed from the third direction DR3.

The front surface of the electronic apparatus ED may be defined as a display surface DS and have a plane defined by the first direction DR1 and the second direction DR2. Images IM generated in the electronic apparatus ED may be provided to a user through the display surface DS.

The display surface DS may include a display region DA and a non-display region NDA surrounding the display region DA. The display region DA may be a region in which an image is displayed, and the non-display region NDA may be a region in which an image IM is not displayed. The non-display region NDA may be adjacent to at least one side of the display region DA. In an embodiment, the non-display region NDA may have a frame shape surrounding the display region DA. However, this is illustrated as an example, and the inventive concept is not limited thereto. For example, the non-display region NDA may be omitted, and when the non-display region NDA is omitted, the display surface DS may only include the display region DA.

The electronic apparatus ED may also sense inputs applied from outside the electronic apparatus ED. For example, the electronic apparatus ED may sense a first input by a touch TC and a second input by a touch pen PEN. The first input by the touch TC may include various forms of external inputs such as a part of a user's body, light, heat, or pressure. The touch pen PEN may be an active pen or an electromagnetic pen. The touch pen PEN may be defined as an input device, and the display region DA may not only display images IM but also include a sensing region that senses the inputs including the touch input from outside.

According to an embodiment of the inventive concept, the electronic apparatus ED may be a large electronic apparatus such as a television, a monitor, or an external billboard. In addition, the electronic apparatus ED may be a small or medium-sized electronic apparatus such as a personal computer, a notebook computer, a personal digital device, an automobile navigation unit, a game console, a smartphone, a tablet, and a camera. However, this is exemplary, and other display devices may also be employed as long as they do not depart from the concept of the present invention. In FIGS. 1A and 1B, the electronic apparatus ED is illustrated as an example to be implemented as a tablet device.

Referring to FIG. 1B, the electronic apparatus ED may output various information through a display module DM within an operating system. When a processor 110 executes an application stored in a memory 120, the display module DM may provide a user with application information through a display panel DP.

The processor 110 may obtain external inputs through an input module 130 or a sensor module 161 and execute an application corresponding to the external inputs. For example, when the user selects a camera icon displayed on the display panel DP, the processor 110 may obtain a user's input through an input sensor 161-2 and activate a camera module 171. The processor 110 may transmit image data, corresponding to a captured image acquired through the camera module 171, to the display module DM. The display module DM may display an image corresponding to the captured image through the display panel DP.

The operation of the electronic apparatus ED has been briefly described above. Hereinafter, the configuration of the electronic apparatus ED will be described in detail. Some of the modules of the electronic apparatus ED described below may be integrated and provided as one component, or a single component may be provided by being separated into two or more modules.

Referring to FIG. 1B, the electronic apparatus ED may communicate with an external electronic apparatus ED-A via a network (e.g., a short-range wireless communication network or a long-range wireless communication network). According to an embodiment of the inventive concept, the electronic apparatus ED may include a processor 110, a memory 120, an input module 130, a display module DM, a power module 150, an embedded module 160, and an external module 170. According to an embodiment of the inventive concept, in the electronic apparatus ED, at least one of the above-described components may be omitted, or one or more other components may be added. According to an embodiment of the inventive concept, some (e.g., the sensor module 161, an antenna module 162, or an audio output module 163) of the above-described components may be integrated into another component (e.g., the display module DM).

The processor 110 may execute software to control at least one other component (e.g., a hardware or software component) of the electronic apparatus ED connected to the processor 110 and perform various data processing or computations. In an embodiment of the inventive concept, as at least part of the data processing or computation, the processor 110 may store commands or data received from other components (e.g., the input module 130, the sensor module 161, or a communication module 173) in volatile memory 121, process the commands or data stored in the volatile memory 121, and store the resulting data in non-volatile memory 122.

The processor 110 may include a main processor 111 and an auxiliary processor 112. The main processor 111 may include at least one of a central processing unit (CPU) 111-1 or an application processor AP. The main processor 111 may further include at least any one of a graphic processing unit (GPU) 111-2, a communication processor CP, or an image signal processor ISP. The main processor 111 may further include a neural processing unit (NPU) 111-3. The neural processing unit 111-3 is a processor specialized in processing an artificial intelligence model, and the artificial intelligence model may be generated through machine learning. The artificial intelligence model may include a plurality of artificial neural network layers. An artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), and deep Q-networks, or a combination of two or more of the above, but is not limited to the examples described above. The artificial intelligence model may additionally or alternatively include a software structure in addition to the hardware structures. At least two of the processing units and processors described above may be implemented as a single integrated component (e.g., a single chip), or each may be implemented as an independent component (e.g., a plurality of chips).

The auxiliary processor 112 may include a controller 112-1. The controller 112-1 may include an interface conversion circuit and a timing control circuit. The controller 112-1 receives an image signal from the main processor 111, converts the data format of the image signal to match the interface specifications of the display module DM, and outputs image data. The controller 112-1 may output various control signals necessary for driving the display module DM.

The auxiliary processor 112 may further include a data conversion circuit 112-2, a gamma correction circuit 112-3, a rendering circuit 112-4, etc. The data conversion circuit 112-2 may receive image data from the controller 112-1, compensate for the image data so that an image is displayed at a desired brightness according to the characteristics of the electronic apparatus ED or the user's settings, or convert the image data to reduce power consumption or compensate for afterimages. The gamma correction circuit 112-3 may convert image data, a gamma reference voltage, or the like so that an image displayed on the electronic apparatus ED has a desired gamma characteristic. The rendering circuit 112-4 may receive image data from the controller 112-1 and render the image data in consideration of the pixel arrangement of the display panel DP. At least one of the data conversion circuit 112-2, the gamma correction circuit 112-3, or the rendering circuit 112-4 may be integrated into another component (e.g., the main processor 111 or the controller 112-1). At least one of the data conversion circuit 112-2, the gamma correction circuit 112-3, or the rendering circuit 112-4 may also be integrated into a data driver DDV to be described below.

The memory 120 may store various data used by at least one component (e.g., the processor 110 or the sensor module 161) of the electronic apparatus ED, and input data or output data related to corresponding commands. The memory 120 may include at least one of volatile memory 121 or non-volatile memory 122.

The input module 130 may receive commands or data to be used or processed at components of the electronic apparatus ED (e.g., the processor 110, the sensor module 161, or the audio output module 163) from outside the electronic apparatus ED (e.g., a user or an external electronic apparatus ED-A).

The input module 130 may include a first input module 131 into which commands or data are input from a user, and a second input module 132 into which commands or data are input from an external electronic apparatus ED-A. The first input module 131 may include a microphone, a mouse, a keyboard, a key (e.g., a button), or a pen (e.g., a passive pen or an active pen). The second input module 132 may support a designated protocol that may be connected to the external electronic apparatus ED-A by wire or wirelessly. According to an embodiment of the inventive concept, the second input module 132 may include a high definition multimedia interface (HDMI), a universal serial bus (USB) interface, an SD card interface, or an audio interface. The second input module 132 may include a connector, such as an HDMI connector, a USB connector, an SD card connector, or an audio connector (e.g., a headphone connector), that may be physically connected to the external electronic apparatus ED-A.

The display module DM visually provides information to a user. The display module DM may include a display panel DP, a scan driver SDC, and a data driver DDV. The display module DM may further include a chassis, a bracket, and a window configured to protect the display panel DP.

The display panel DP may include a liquid crystal display panel, an organic light-emitting display panel, or an inorganic light-emitting display panel,. However, the type of the display panel DP is not particularly limited thereto. The display panel DP may be a rigid type or a flexible type that can be rolled or folded. The display module DM may further include a heat dissipation member, a bracket, or a supporter configured to support the display panel DP.

The scan driver SDC may be mounted on the display panel DP as a driving chip. In addition, the scan driver SDC may be integrated into the display panel DP. For example, the scan driver SDC may include an amorphous silicon TFT gate driver circuit (ASG), a low temperature polycrystalline silicon (LTPS) TFT gate driver circuit, or an oxide semiconductor TFT gate driver circuit (OSG) embedded in the display panel DP. The scan driver SDC receives a control signal from the controller 112-1 and outputs scan signals to the display panel DP in response to the control signal.

The display panel DP may further include a light-emitting driver. The light-emitting driver outputs a light-emitting control signal to the display panel DP in response to the control signal received from the controller 112-1. The light-emitting driver may be formed separately from the scan driver SDC or may be integrated into the scan driver SDC.

The data driver DDV receives a control signal from the controller 112-1, converts image data into an analog voltage (e.g., a data voltage) in response to the control signal, and outputs the data voltages to the display panel DP.

The data driver DDV may be integrated into another component (e.g., the controller 112-1). The functions of the interface conversion circuit and the timing control circuit of the above-described controller 112-1 may be integrated into the data driver DDV.

The display module DM may further include a light-emitting driver, a voltage generating circuit, or the like. The voltage generating circuit may output various voltages required for driving the display panel DP.

The power module 150 supplies power to components of the electronic apparatus ED. The power module 150 may include a battery that charges a power voltage. The battery may include a non-rechargeable primary battery, a rechargeable secondary battery, or a fuel cell. The power module 150 may further include a power management integrated circuit (PMIC). The PMIC supplies power optimized for each of the modules described above and below. The power module 150 may further include a wireless power transmission/reception member electrically connected to the battery. The wireless power transmission/reception member may include a plurality of coil-shaped antenna radiators.

The electronic apparatus ED may further include an embedded module 160, and an external module 170. The embedded module 160 may include a sensor module 161, an antenna module 162, and an audio output module 163. The external module 170 may include a camera module 171, a light module 172, and a communication module 173.

The sensor module 161 may sense an input by a user's body or an input by a pen among the first input modules 131, and generate a data value or an electrical signal corresponding to the input. The sensor module 161 may include at least one of a fingerprint sensor 161-1, an input sensor 161-2, or a digitizer 161-3.

The fingerprint sensor 161-1 may generate a data value corresponding to a user's fingerprint. The fingerprint sensor 161-1 may include either an optical fingerprint sensor or a capacitive fingerprint sensor.

The input sensor 161-2 may generate a data value corresponding to the coordinate information of an input by a user's body or an input by a pen. The input sensor 161-2 generates the data value based on a change in capacitance caused by the input. The input sensor 161-2 may sense an input by a passive pen, or communicate with an active pen to transmit and receive data.

The input sensor 161-2 may also measure a biometric signal, such as blood pressure, moisture, or body fat. For example, when a user touches a part of his or her body to a sensor layer or a sensing panel and does not move for a certain period of time, the input sensor 161-2 may sense the biometric signal based on an amount of change in electric field caused by the body part and output the information desired by the user to the display module DM.

The digitizer 161-3 may generate a data value corresponding to the coordinate information of an input by a pen. The digitizer 161-3 generates the data value based on an amount of change in electromagnetic field caused by the input. The digitizer 161-3 may sense an input by a passive pen, or communicate with an active pen to transmit and receive data.

At least one of the fingerprint sensor 161-1, the input sensor 161-2, or the digitizer 161-3 may be implemented as a sensor layer formed on the display panel DP. The fingerprint sensor 161-1, the input sensor 161-2, and the digitizer 161-3 may be disposed on the upper side of the display panel DP, and any one of the fingerprint sensor 161-1, the input sensor 161-2, and the digitizer 161-3, for example, the digitizer 161-3, may be disposed on the lower side of the display panel DP.

At least two of the fingerprint sensor 161-1, the input sensor 161-2, and the digitizer 161-3 may be formed to be integrated into one sensing panel through a same manufacturing process. When they are integrated into one sensing panel, the sensing panel may be disposed between the display panel DP and the window disposed on the upper side of the display panel DP. According to an embodiment of the inventive concept, the sensing panel may be disposed on the window, and the position of the sensing panel is not particularly limited thereto.

At least one of the fingerprint sensor 161-1, the input sensor 161-2, or the digitizer 161-3 may be embedded in the display panel DP. That is, at least one of the fingerprint sensor 161-1, the input sensor 161-2, or the digitizer 161-3 may be formed simultaneously through a same manufacturing process to form elements (e.g., a light-emitting element, a transistor, and the like) included in the display panel DP.

In addition, the sensor module 161 may generate an electrical signal or data value corresponding to an internal state or an external state of the electronic apparatus ED. The sensor module 161 may further include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 162 may include one or more antennas configured to transmit a signal or power to the outside, or to receive a signal or power from the outside. According to an embodiment of the inventive concept, the communication module 173 may transmit a signal to or receive a signal from an external electronic apparatus through an antenna suitable for a communication method. The antenna pattern of the antenna module 162 may be integrated into one component of the display module DM (e.g., a display panel DP) or the input sensor 161-2.

The audio output module 163 is a device configured to output an audio signal to the outside of the electronic apparatus ED, and may include, for example, a speaker used for general purposes, such as multimedia playback or recorded audio playback, and a receiver used exclusively for telephone reception. According to an embodiment of the inventive concept, the receiver may be formed integrally with or separately from the speaker. The audio output pattern of the audio output module 163 may be integrated into the display module DM.

The camera module 171 may capture still images and moving images. According to an embodiment of the inventive concept, the camera module 171 may include one or more lenses, an image sensor, or an image signal processor. The camera module 171 may further include an infrared camera capable of measuring the presence or absence of a user, the location of the user, the gaze of the user, etc.

The light module 172 may provide light. The light module 172 may include a light-emitting diode or a xenon lamp. The light module 172 may operate in conjunction with the camera module 171 or may operate independently.

The communication module 173 may support the establishment of a wired or wireless communication channel between the electronic apparatus ED and the external electronic apparatus ED-A, and the communication between the electronic apparatus ED and the external electronic apparatus ED-A through the established communication channel. The communication module 173 may include any one or all of a wireless communication module, such as a cellular communication module, a short-range wireless communication module, or a global navigation satellite system (GNSS) communication module, and a wired communication module such as a local area network (LAN) communication module or a power line communication module. The communication module 173 may communicate with the external electronic apparatus ED-A through a short-range communication network such as Bluetooth, WiFi, or IrDA (infrared data association), or a long-range communication network such as a cellular network, the Internet, or a computer network (e.g., a LAN or WAN). The various types of communication modules 173 described above may be implemented as one chip or as separate chips.

The input module 130, the sensor module 161, the camera module 171, etc. may be used to control the operation of the display module DM in conjunction with the processor 110.

The processor 110 outputs commands or data to the display module DM, the audio output module 163, the camera module 171, or the light module 172 based on input data received from the input module 130. For example, the processor 110 may generate image data in response to the input data received from a mouse or an active pen, etc. and output the image data to the display module DM, or generate command data in response to the input data and output the command data to the camera module 171 or the light module 172. When no input data is received from the input module 130 for a certain period of time, the processor 110 may reduce power consumed by the electronic apparatus ED by switching the operation mode of the electronic apparatus ED to a low-power mode or a sleep mode.

The processor 110 outputs commands or data to the display module DM, the audio output module 163, the camera module 171, or the light module 172 based on sensing data received from the sensor module 161. For example, the processor 110 may compare information, e.g., a user's fingerprint information, applied through the fingerprint sensor 161-1 with authentication data stored in the memory 120 and then execute an application based on the comparison result. The processor 110 may execute commands or output corresponding image data to the display module DM based on sensing data sensed by the input sensor 161-2 or the digitizer 161-3. When the sensor module 161 includes a temperature sensor, the processor 110 may receive temperature data from the sensor module 161 and further perform brightness correction, etc. on the image data based on the temperature data.

The processor 110 may receive data regarding the presence or absence of a user, the location of the user, the gaze of the user, etc. from the camera module 171. The processor 110 may further perform brightness correction, etc. on the image data based on the received data. For example, the processor 110 that has determined the presence or absence of a user through an input from the camera module 171 may output the image data, whose brightness has been corrected through the data conversion circuit 112-2 or the gamma correction circuit 112-3, to the display module DM.

Some of the above components may be connected to each other through a communication method between peripheral devices, such as a bus, a general purpose input/output (GPIO), a serial peripheral interface (SPI), a mobile industry processor interface (MIPI), or an ultra path interconnect (UPI) link, and may exchange signals (e.g., commands or data) with each other. The processor 110 may communicate with the display module DM through a mutually agreed interface and use, for example, any one of the above-described communication methods.

The electronic apparatus ED according to various embodiments of the inventive concept disclosed in the specification may be implemented in various forms. The electronic apparatus ED may include, for example, at least one of a portable communication device (e.g., a smart phone), a computer device, a portable multimedia device, a portable medical device, a camera, a wearable device, or a home appliance device.

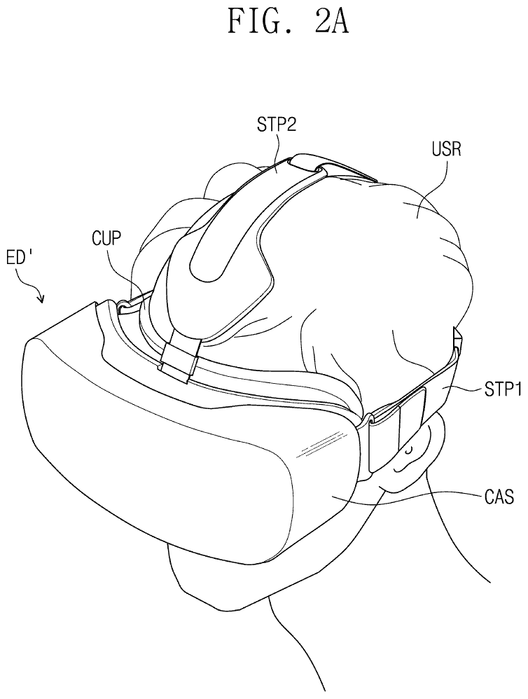

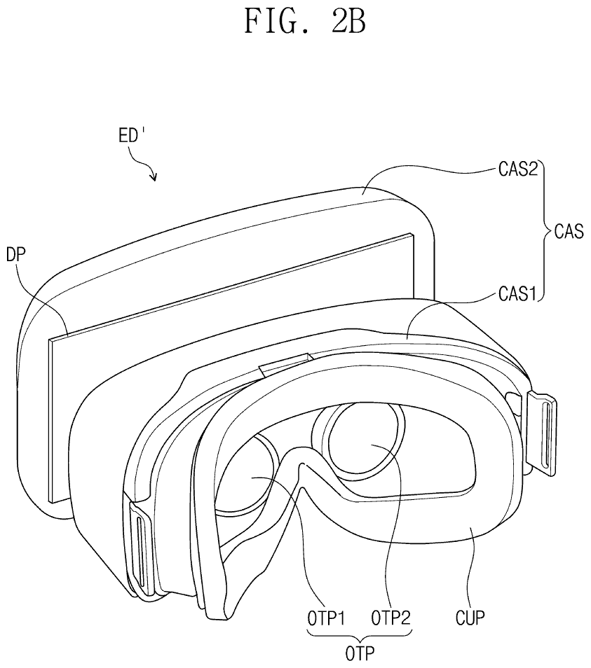

FIGS. 2A and 2B are perspective views of an electronic apparatus according to an embodiment of the inventive concept.

Referring to FIG. 2A, an electronic apparatus ED′ according to an embodiment of the inventive concept may be implemented as a head-mounted display device. The electronic apparatus ED′ may be worn on the head of a user USR.

The electronic apparatus ED′ may block the peripheral vision of the user USR and provide an image to the user USR. The electronic apparatus ED′ may provide virtual reality to the user USR.

The electronic apparatus ED′ may include a case portion CAS, a cushion portion CUP, and strap portions STP1 and STP2. The case portion CAS may be worn by the user USR. A display panel DP configured to display an image and an acceleration sensor (not illustrated) may be accommodated inside the case portion CAS.

The acceleration sensor may sense the movement of the user USR and transmit a predetermined signal to the display panel DP. Therefore, the display panel DP may provide an image corresponding to a change in the gaze of the user USR. As a result, the user USR may experience virtual reality similar to actual reality.

The cushion portion CUP may be disposed between the case portion CAS and the user USR. The cushion portion CUP may include a material that is easily deformable. For example, the cushion portion CUP may include a polymer resin (for example, polyurethane (PU), polycarbonate (PC), polypropylene, and polyethylene (PE)). In addition, the cushion portion CUP may include a sponge formed of a rubber solution, a urethane-based material, or an acrylic-based material.

The cushion portion CUP may allow the case portion CAS to closely adhere to the user USR, thereby improving the wearing comfort of the user USR. The cushion portion CUP may be attachable to and detachable from the case portion CAS.

The strap portions STP1 and STP2 may be coupled to the case portion CAS to allow the case portion CAS to be easily worn by the user USR. The strap portions STP1 and STP2 may include a first strap portion STP1 and a second strap portion STP2.

The first strap portion STP1 may be worn along the circumference of the head of the user USR. The first strap portion STP1 may fix the case portion CAS to the user USR so that the case portion CAS can closely adhere to the head of the user USR.

The second strap portion STP2 may connect the case portion CAS and the first strap portion STP1 to each other along the upper portion of the head of the user USR. The second strap portion STP2 may prevent the case portion CAS from slipping down.

Referring to FIG. 2B, the case portion CAS may include a first case portion CAS1 and a second case portion CAS2. The first case portion CAS1 and the second case portion CAS2 may be separated from each other.

The display panel DP may be disposed between the first case portion CAS1 and the second case portion CAS2. The display panel DP may be accommodated inside the case portion CAS formed by the first case portion CAS1 and the second case portion CAS2 coupled to each other. For example, the display panel DP may provide a left-eye image and a right-eye image to the user. Therefore, the display panel DP may provide a stereoscopic image to the user.

An optical system OTP may be disposed inside the first case portion CAS1. The optical system OTP may magnify an image provided from the display panel DP. The optical system OTP may be disposed between the display panel DP and the eye of the user USR, when the user USR wears the electronic apparatus ED′. The optical system OTP may include a left-eye optical system OTP1 and a right-eye optical system OTP2. The left-eye optical system OTP1 may magnify and provide an image to the left pupil of the user USR, and the right-eye optical system OTP2 may magnify and provide an image to the right pupil of the user USR.

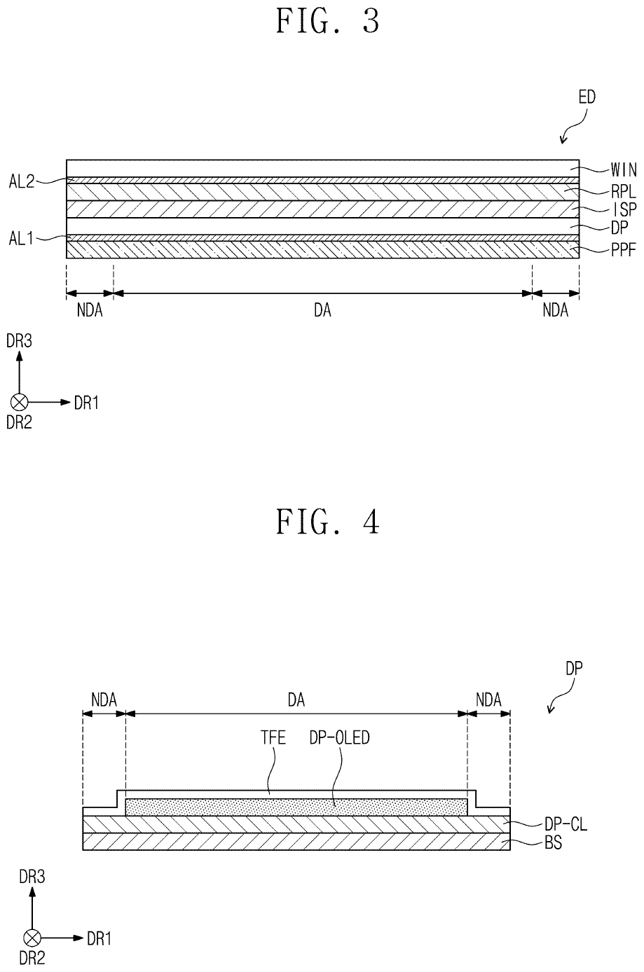

FIG. 3 illustrates a cross section of the electronic apparatus illustrated in FIG. 1A. FIG. 4 illustrates a cross section of the display panel illustrated in FIG. 3.

Referring to FIG. 3, the electronic apparatus ED may include a display panel DP, an input sensing portion ISP, a reflection prevention layer RPL, a window WIN, a panel protection film PPF, and first and second adhesive layers AL1 and AL2. The display panel DP may correspond to the above-described display panel DP (see FIG. 1B), and the input sensing portion ISP may correspond to the above-described sensor module 161 (see FIG. 1B).

The display panel DP according to an embodiment of the inventive concept may be a light-emitting display panel. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include quantum dots, quantum rods, or the like. Hereinafter, the embodiment of the inventive concept will be explained as assuming that the display panel DP is implemented as an organic light-emitting display panel for convenience of description.

Referring to FIG. 4, the display panel DP may include a base layer BS, a circuit element layer DP-CL, a display element layer DP-OLED, and a thin film encapsulation layer TFE. The circuit element layer DP-CL, the display element layer DP-OLED, and the thin film encapsulation layer TFE may be sequentially disposed on the base layer BS.

The base layer BS may include glass or a flexible plastic material such as polyimide (PI).

A plurality of pixels may be disposed in the circuit element layer DP-CL and the display element layer DP-OLED. Each of the pixels may include a transistor disposed in the circuit element layer DP-CL and a light-emitting element disposed in the display element layer DP-OLED, and the transistor in the circuit element layer DP-CL and the light-emitting element in the display element layer DP-OLED are connected to each other.

The thin film encapsulation layer TFE may be disposed on the circuit element layer DP-CL and the display element layer DP-OLED so as to protect the pixels from moisture, oxygen, and external foreign substances. According to an embodiment, the thin film encapsulation layer TFE may cover the entire region of the base layer BS. However, the embodiment of the inventive concept is not limited thereto. For example, the base layer BS may include a partial region not covered by the thin film encapsulation layer TFE. The region of the base layer BS not covered by the thin film encapsulation layer TFE may be formed along the edge of the base layer BS.

Referring to FIG. 3, the input sensing portion ISP may be disposed on the display panel DP. The input sensing portion ISP may include a plurality of sensing units (not illustrated) configured to sense an external input in a capacitive manner. The input sensing portion ISP may be formed directly on the display panel DP during the manufacturing of the electronic apparatus ED. Specifically, a conductive pattern or an insulating layer included in the input sensing portion ISP may be directly deposited or patterned on the display panel DP. However, the embodiment of the inventive concept is not limited thereto, and the input sensing portion ISP may be manufactured as a panel separate from the display panel DP and be attached to the display panel DP by an adhesive layer.

Referring to FIG. 3, the reflection prevention layer RPL may be disposed on the input sensing portion ISP. The reflection prevention layer RPL may reduce the reflectance of the external light incident from outside of the electronic apparatus ED, thereby improving the visibility of an image displayed on the electronic apparatus ED. The reflection prevention layer RPL may include a retarder, a polarizer, a black matrix, or a color filter. The reflection prevention layer RPL may be formed directly on the input sensing portion ISP through a coating or deposition process, or may be provided in the form of a film and attached to the input sensing portion ISP by an adhesive layer.

The window WIN may be disposed on the reflection prevention layer RPL. The window WIN may protect the display panel DP, the input sensing portion ISP, and the reflection prevention layer RPL from external scratches and impacts.

The panel protection film PPF may be disposed below the display panel DP. The panel protection film PPF may support the display panel DP and protect the lower portion of the display panel DP. The panel protection film PPF may have insulating properties. For example, the panel protection film PPF may include a resin such as polyethylene terephthalate (PET), polyimide, or polypropylene (PP).

The first adhesive layer AL1 may be disposed between the display panel DP and the panel protection film PPF, and the display panel DP and the panel protection film PPF may be bonded to each other by the first adhesive layer AL1. The second adhesive layer AL2 may be disposed between the window WIN and the reflection prevention layer RPL, and the window WIN and the reflection prevention layer RPL may be bonded to each other by the second adhesive layer AL2.

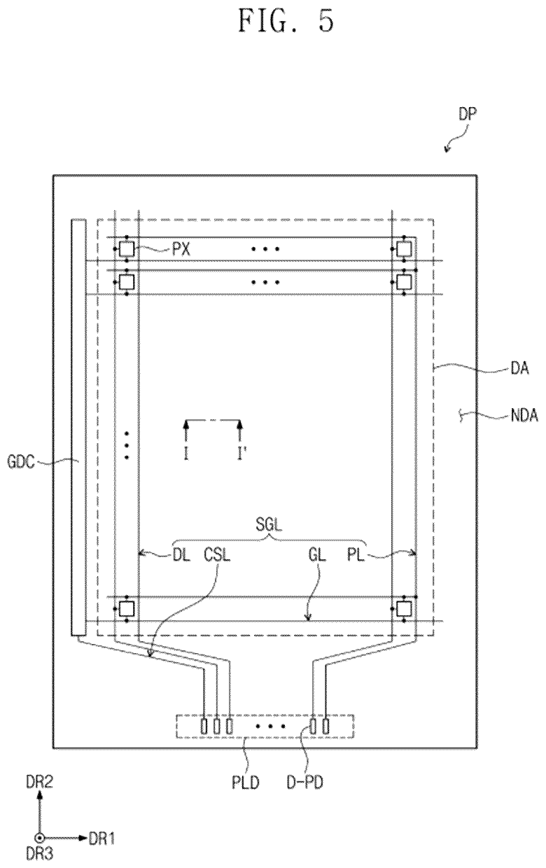

FIG. 5 is a plan view of the display panel according to an embodiment of the inventive concept. For ease of explanation, FIG. 5 briefly illustrates some components of the display panel DP.

Referring to FIG. 5, the display panel DP may include pixels PX, signal lines SGL, a driving circuit GDC, and a pad portion PLD. The display panel DP may include the pixels PX, the signal lines SGL electrically connected to the pixels PX, the driving circuit GDC, and the pad portion PLD.

The pixels PX may be disposed in the display region DA. The pixels PX may be arranged in the first direction DR1 and the second direction DR2. The pixels PX may include a plurality of pixel rows extending in the first direction DR1 and arranged in the second direction DR2, and a plurality of pixel columns extending in the second direction DR2 and arranged in the first direction DR1.

Each of the pixels PX may include a light-emitting element and a pixel driver configured to drive the light-emitting element. The light-emitting element may include an organic light-emitting diode, and the pixel driver may include a capacitor and at least one transistor connected to the light-emitting element.

The signal lines SGL may include gate lines GL, data lines DL, a power line PL, and a control signal line CSL. Each of the gate lines GL may be connected to a corresponding pixel PX among the pixels PX, and each of the data lines DL may be connected to a corresponding pixel PX among the pixels PX. The power line PL may be electrically connected to the pixels PX. The control signal line CSL may be connected to the driving circuit GDC and provide control signals to the driving circuit GDC.

The driving circuit GDC may include a gate driving circuit. The gate driving circuit may generate gate signals and sequentially output the generated gate signals to the pixels PX through the gate lines GL. The gate driving circuit may further output another control signal to the pixel driver.

The pad portion PLD may be a portion to which a circuit board (not illustrated) is connected. The pad portion PLD may include pixel pads D-PD, and the pixel pads D-PD may be configured to connect a flexible circuit board to the display panel DP. Each of the pixel pads D-PD may be connected to a corresponding signal line among the signal lines SGL. One of the pixel pads D-PD may be connected to the control signal line CSL so as to transmit a control signal to the driving circuit GDC. Some of the pixel pads D-PD may be connected to the data line DL so as to transmit data signals to each of the pixels PX.

In addition, the pad portion PLD may further include input pads. The input pads may be configured to connect a circuit board to the input sensing portion ISP (see FIG. 3). Without being limited thereto, however, the input pads may be disposed in the input sensing portion ISP (see FIG. 3) and connected to a circuit board, independently from the pixel pads D-PD. If the electronic apparatus ED does not include the input sensing portion ISP, the input pads connecting a circuit board to the input sensing portion ISP would not be included in the electronic apparatus ED.

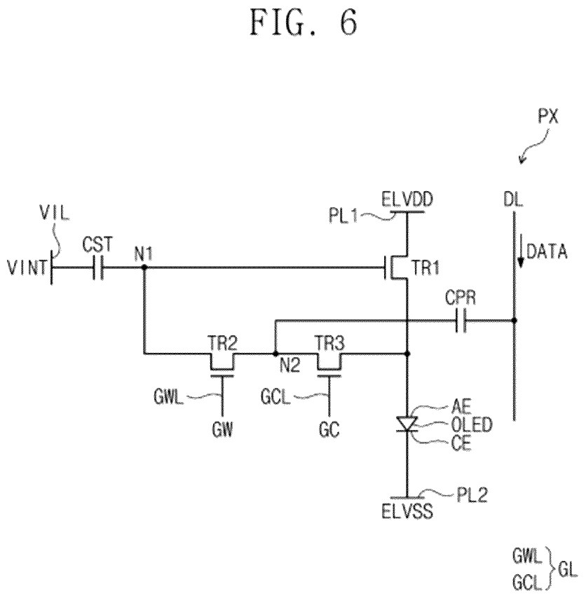

FIG. 6 illustrates an equivalent circuit of a pixel included in the display panel illustrated in FIG. 5.

Referring to FIG. 6, the pixel PX may include a first transistor TR1, a second transistor TR2, a third transistor TR3, a light-emitting element OLED, and a storage capacitor CST, and a parasitic capacitor CPR.

The gate line GL may include a write gate line GWL and a compensation gate line GCL. The write gate line GWL may receive a write gate signal GW, and the compensation gate line GCL may receive a compensation gate signal GC.

A parasitic capacitor CPR (or a first capacitor) may be formed between the data line DL and a second node N2 disposed between the second transistor TR2 and the third transistor TR3. By utilizing a capacitance formed through the parasitic capacitor CPR, it is possible to provide a required capacitance without additionally forming a separate capacitor. This may simplify the circuit design and reduce the manufacturing cost. According to an embodiment, by placing the parasitic capacitor CPR, disposed between the transistors, on a layer different from that of the storage capacitor CST (or second capacitor), it is possible to sufficiently secure an area for an electrode of the parasitic capacitor CPR. Accordingly, an electronic apparatus with increased resolution may be provided. A detailed description thereof will be provided later.

The light-emitting element OLED may include an organic light-emitting element. The light-emitting element OLED may include an anode AE and a cathode CE. The anode AE may be connected to a first power line PL1 through the first transistor TR1. The cathode CE may be connected to a second power line PL2. The first power line PL1 may receive a first voltage ELVDD. The second power line PL2 may receive a second voltage ELVSS having a lower voltage level than the first voltage ELVDD.

Each of the first transistor TR1 to the third transistor TR3 may be an NMOS transistor. The first transistor TR1 may include a silicon semiconductor, and the second and third transistors TR2 and TR3 may include an oxide semiconductor. However, the embodiment of the inventive concept is not limited thereto, and each of the second and third transistors TR2 and TR3 may be a PMOS transistor.

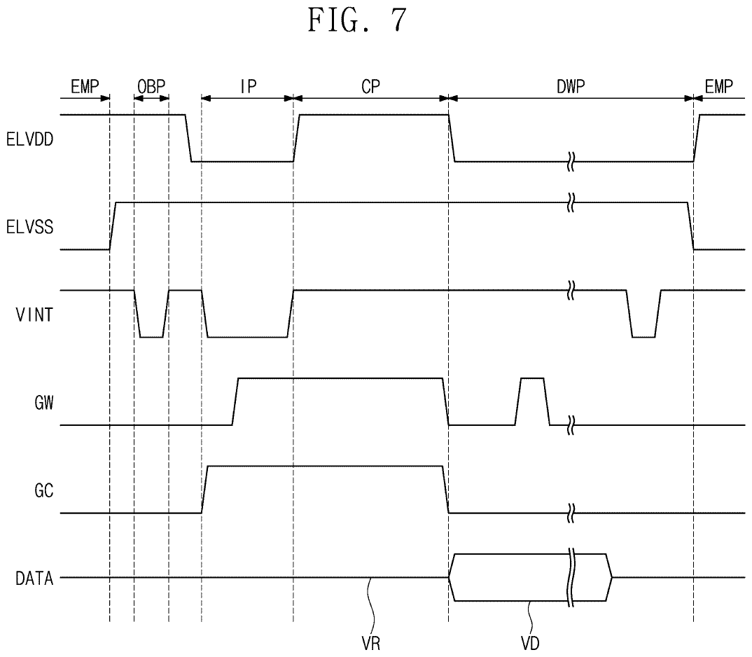

Each of the first, second, and third transistors TR1, TR2, and TR3 may include a source electrode, a drain electrode, and a gate electrode. Hereinafter, in FIG. 7, for convenience of explanation, any one of the source electrode and the drain electrode will be referred to as a first electrode, and the other electrode of the source electrode and the drain electrode will be referred to as a second electrode. In addition, the gate electrode will be referred to as a control electrode.

The first transistor TR1 may be referred to as a driving transistor, and the second transistor TR2 may be referred to as a switching transistor. The third transistor TR3 may be referred to as a compensation transistor.

The first transistor TR1 may be connected to the first power line PL1 and the anode AE of the light-emitting element OLED, and may be turned on or turned off in response to the voltage of a first node N1. The first transistor TR1 may include a first electrode connected to the first power line PL1, a second electrode connected to the anode AE of the light-emitting element OLED, and a control electrode connected to the first node N1. The first transistor TR1 may be turned on in response to the voltage of the first node N1. The first node N1 may be connected to the control electrode of the first transistor TR1.

The second transistor TR2 may be connected to the first node N1 and the second node N2. Specifically, the second transistor TR2 may be connected to the control electrode of the first transistor TR1 and the data line DL. The second transistor TR2 may be turned on or turned off in response to the write gate signal GW.

The second transistor TR2 may include a first electrode connected to the first node N1, a second electrode connected to the second node N2, and a control electrode connected to the write gate line GWL. The second transistor TR2 may be turned on in response to the write gate signal GW applied through the write gate line GWL.

The third transistor TR3 may be connected to the second node N2 and the anode AE of the light-emitting element OLED, and turned on or turned off in response to the compensation gate signal GC. The third transistor TR3 may include a first electrode connected to the second node N2, a second electrode connected to the anode AE of the light-emitting element OLED, and a control electrode connected to the compensation gate line GCL. The third transistor TR3 may be turned on in response to the compensation gate signal GC applied through the compensation gate line GCL.

The data line DL may be connected to the second node N2. Therefore, the data line DL may be connected to the second electrode of the second transistor TR2 and the first electrode of the third transistor TR3. The data line DL may receive a data signal DATA.

The anode AE of the light-emitting element OLED may be connected to the first power line PL1 through the first transistor TR1, and the cathode CE of the light-emitting element OLED may be connected to the second power line PL2.

The storage capacitor CST may include a first electrode connected to an initialization line VIL and a second electrode connected to the first node N1. The initialization line VIL may receive an initialization voltage VINT.

The write gate signal GW applied to the control electrode of the second transistor TR2 may be a global clock signal for simultaneous light-emitting driving. For example, when the display device operates in a simultaneous light-emitting driving manner, the write gate signal GW, which is a global clock signal, may be commonly applied to the pixels PX.

FIG. 7 is a timing diagram of signals for operating the pixel illustrated in FIG. 6.

Referring to FIGS. 6 and 7, the operation periods of the pixel PX may include an on-bias period OBP, an initialization period IP, a compensation period CP, a data write period DWP, and a light-emitting period EMP.

The pixel PX may perform an on-bias operation in the on-bias period OBP and an initialization operation in the initialization period IP. The pixel PX may perform a threshold voltage compensation operation in the compensation period CP, a data write operation in the data write period DWP, and a light-emitting operation in the light-emitting period EMP.

In the on-bias period OBP, the first voltage ELVDD may have a high voltage level, the second voltage ELVSS may have a high voltage level, and the initialization voltage VINT may have a low voltage level. In the on-bias period OBP, the write gate signal GW and the compensation gate signal GC may have a low level (e.g., an inactive level), and the data signal DATA may have a reference voltage VR having a preset voltage level.

In the on-bias period OBP, an on-bias operation may be performed in the pixel PX, and accordingly, the voltage characteristic curve of the first transistor TR1 may be initialized to an on-bias state, regardless of the data signal DATA supplied in a previous frame. As a result, the pixel PX may generate a desired brightness regardless of the data signal DATA supplied in the previous frame.

In the on-bias period OBP, the initialization voltage VINT having a low voltage level is transmitted to the control electrode of the first transistor TR1. Since both the first voltage ELVDD and the second voltage ELVSS have a high voltage level, the first transistor TR1 may not be turned on. In response to the write gate signal GW having an inactive level and the compensation gate signal GC having an inactive level, the second and third transistors TR2 and TR3 may be turned off.

In the initialization period IP, the first voltage ELVDD may have a low voltage level, the second voltage ELVSS may have a high voltage level, and the initialization voltage VINT may have a low voltage level. In the initialization period IP, the write gate signal GW may transition from a low level to a high level (e.g., an activation level), the compensation gate signal GC may have a high level (e.g., an activation level), and the data signal DATA may have the reference voltage VR.

Therefore, the second transistor TR2 may change from a turned-off state to a turned-on state, and the third transistor TR3 may be turned on in the initialization period IP. Since the second and third transistors TR2 and TR3 are turned on, the first node N1 may be connected to the second node N2, and the second node N2 may be connected to the anode AE of the light-emitting element OLED. According to the initialization voltage VINT having a low voltage level, the first node N1 (i.e., the control electrode of the first transistor TR1) may be initialized, the second node N2 connected to the first node N1 may be initialized, and the anode AE of the light-emitting element OLED connected to the second node N2 may be initialized.

In the compensation period CP, the first voltage ELVDD may have a high voltage level, the second voltage ELVSS may have a high voltage level, and the initialization voltage VINT may have a high voltage level. In the compensation period CP, the write gate signal GW may have a high level, the compensation gate signal GC may have a high level, and the data signal DATA may have the reference voltage VR.

As the initialization voltage VINT provided to the control electrode of the first transistor TR1 has a high voltage level, and each of the write gate signal GW provided to the control electrode of the second transistor TR2, and the compensation gate signal GC provided to the control electrode of the third transistor TR3 has a high level (e.g., an activation level), each of the first transistor TR1, the second transistor TR2, and the third transistor TR3 may be turned on and the first transistor TR1 may be connected in a diode form. In this case, a voltage reflecting a threshold voltage of the first transistor TR1 is stored in the first node N1, and accordingly, a characteristic variation caused by the threshold voltage of the first transistor TR1 may be eliminated. The operation of connecting the first transistor TR1 in a diode form may be referred to as a threshold voltage compensation operation.

In the data write period DWP, the first voltage ELVDD may have a low voltage level, and the second voltage ELVSS may have a high voltage level. In the data write period DWP, the initialization voltage VINT may transition from a high voltage level to a low voltage level and then transition from a low voltage level to a high voltage level after a predetermined time has elapsed.

In the data write period DWP, the write gate signal GW may transition from a low level to a high level and then transition from a high level to a low level after a predetermined time (e.g., a data write operation time) has elapsed. In the data write period DWP, the compensation gate signal GC may have a low level, and the data signal DATA may have a data voltage VD having a voltage level corresponding to a predetermined grayscale.

During the activation period (e.g., a high level) of the write gate signal GW, the second transistor TR2 may be turned on, and the third transistor TR3 may be turned off. During the data write operation time in which the second transistor TR2 is turned on, the data signal DATA may be stored in the storage capacitor CST.

In the light-emitting period EMP, the first voltage ELVDD may have a high voltage level, the second voltage ELVSS may have a low voltage level, and the initialization voltage VINT may have a high voltage level. The write gate signal GW may have a low level, the compensation gate signal GC may have a low level, and the data signal DATA may have the reference voltage VR.

In the light-emitting period EMP, the first transistor TR1 may be turned on based on the data signal DATA stored in the storage capacitor CST. Accordingly, current may flow to the light-emitting element OLED so that the light-emitting element OLED may emit light.

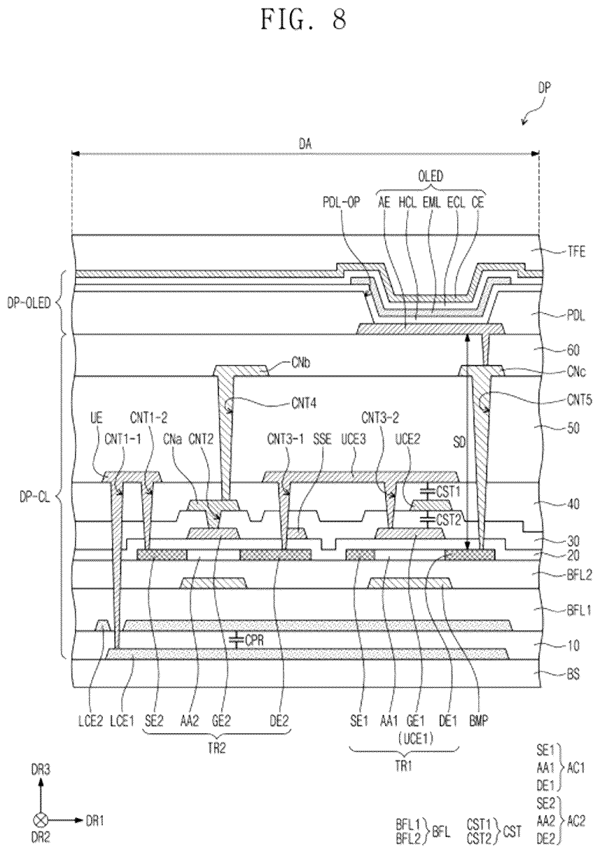

FIG. 8 is a cross-sectional view of the display panel taken along a line I-I′ of FIG. 5.

Referring to FIG. 8, the display panel DP may include a base layer BS, a circuit element layer DP-CL, a display element layer DP-OLED, and a thin film encapsulation layer TFE.

The display panel DP may include a plurality of insulating layers, a semiconductor pattern, a conductive pattern, a signal line, and the like. An insulating layer, a semiconductor layer, and a conductive layer are formed by coating, deposition, etc. Hereafter, for convenience of description, the embodiment of the inventive concept will be explained as assuming that each of the insulating layer, the semiconductor layer, and the conductive layer may be selectively patterned by photolithography and etching processes. In this way, the semiconductor pattern, the conductive pattern, the signal line SGL, and the like included in the circuit element layer DP-CL and the display element layer DP-OLED may be formed.

The base layer BS may include a glass substrate, a sapphire substrate, a plastic film, or an organic/inorganic stacked film. The base layer BS may have a multi-layer or single-layer structure. For example, the base layer BS may have a stacked structure in which a plurality of plastic films are bonded to each other by an adhesive, or may have a stacked structure in which a glass substrate and a plastic film are bonded to each other by an adhesive. The base layer BS may have flexibility. For example, the base layer BS may include polyimide. However, this is described as an example, and the base layer BS may be provided in a rigid state.

The circuit element layer DP-CL may include pixel drivers, lower conductive patterns BMP, buffer layers BFL, and first to sixth insulating layers 10, 20, 30, 40, 50, and 60.

Referring to FIG. 8, the circuit element layer DP-CL may be disposed on the base layer BS. For ease of explanation, FIG. 8 illustrates two transistors TR1 and TR2, two capacitors CPR and CST, an upper electrode UE, and a plurality of connection electrodes CNa, CNb, and CNc included in the pixel drivers, and also illustrates the first to sixth insulating layers 10, 20, 30, 40, 50, and 60 which are sequentially stacked. It is noted that this configuration of the circuit element layer DP-CL in FIG. 8 is illustrated as an example, and the configuration or arrangement relationship of the pixel drivers included in the circuit element layer DP-CL may be variously modified.

The buffer layer BFL may be disposed on the base layer BS. The buffer layer BFL may improve the bonding strength between the base layer BS and the semiconductor pattern. The buffer layer BFL may include a silicon oxide layer and/or a silicon nitride layer. When the buffer layer BFL includes a silicon oxide layer and a silicon nitride layer, the two layers may be alternately stacked.

Referring to FIG. 8, the buffer layer BFL may be provided as a plurality of layers. The buffer layer BFL may include a first buffer layer BFL1 and a second buffer layer BFL2. The first buffer layer BFL1 may cover the first capacitor CPR. The second buffer layer BFL2 may cover the lower conductive patterns BMP. However, the embodiment of the inventive concept is not limited thereto, and the buffer layer BFL may be a single layer.

The lower conductive patterns BMP may be disposed on the base layer BS. The lower conductive patterns BMP may be disposed between the first capacitor CPR and the first transistor TR1, and/or be disposed between the first capacitor CPR and the second transistor TR2. The lower conductive patterns BMP may be included in the pixel PX (see FIG. 6). The lower conductive patterns BMP may include a conductive material and a metal. The lower conductive patterns BMP may include a light-blocking material. The lower conductive patterns BMP may include a same material as each other, but the embodiment of the inventive concept is not limited thereto. For example, the lower conductive patterns BMP may include different materials from each other. For convenience of description, FIG. 8 only illustrates that the lower conductive patterns BMP is disposed below the first transistor TR1 and the second transistor TR2. However, the embodiment of the inventive concept is not limited thereto. For example, the lower conductive patterns BMP may be disposed to overlap the transistors TR1 and TR2 and the like, e.g., a third transistor TR3 (see FIG. 6) included in the pixel PX to protect the semiconductor patterns and the like of the transistors TR1, TR2 and/or TR3. The lower conductive patterns BMP may be disposed below the transistors TR1 and TR2 to block the influence of an electric potential on the transistors TR1 and TR2, or to block external light from reaching the transistors TR1 and TR2.

The lower conductive patterns BMP may respectively overlap semiconductor patterns AC1 and AC2. Any one of the lower conductive patterns BMP may overlap a first semiconductor pattern AC1, and another one of the lower conductive patterns BMP may overlap a second semiconductor pattern AC2. By respectively placing the lower conductive patterns BMP to overlap the semiconductor patterns AC1 and AC2 of the transistors TR1 and TR2, electrical interference on the transistors TR1 and TR2 from the conductive layers disposed below the transistors TR1 and TR2 may be minimized.

The insulating layers 10, 20, 30, 40, 50, and 60 may include first to sixth insulating layers 10, 20, 30, 40, 50, and 60 sequentially stacked on the base layer BS, but this is merely an example, and the number of the insulating layers included in the circuit element layer DP-CL may vary.

The transistors TR1 and TR2 may be disposed on the buffer layers BFL1 and BFL2. The transistors TR1 and TR2 may include a first transistor TR1 and a second transistor TR2. In this case, the first transistor TR1 may correspond to the first transistor TR1 of FIG. 6, and the second transistor TR2 may correspond to the second transistor TR2 of FIG. 6. The first transistor TR1 may be referred to as a driving transistor, and the second transistor TR2 may be referred to as a switching transistor. However, the embodiment of the inventive concept is not limited thereto.

The first transistor TR1 may include a first semiconductor pattern AC1 and a first gate electrode GE1. The second transistor TR2 may be disposed on the same layer as the first transistor TR1. The second transistor TR2 may include a second semiconductor pattern AC2 and a second gate electrode GE2. Each of the first semiconductor pattern AC1 and the second semiconductor pattern AC2 may be disposed between the first capacitor CPR and the second capacitor CST.

The semiconductor patterns AC1 and AC2 may be disposed on the buffer layer BFL1 and BFL2. Each of the semiconductor patterns AC1 and AC2 may be disposed to overlap the lower conductive pattern BMP. The semiconductor patterns AC1 and AC2 may include polysilicon. Without being limited thereto, however, the semiconductor patterns AC1 and AC2 may include amorphous silicon or metal oxide. FIG. 8 only illustrates some semiconductor patterns AC1 and AC2 as an example, but at least one semiconductor pattern may be further disposed within a plurality of light-emitting regions. The semiconductor patterns AC1 and AC2 may include a plurality of regions that are divided according to conductivity.

Each of the semiconductor patterns AC1 and AC2 may include a source region SE1 or SE2 (or a source electrode), an active region AA1 or AA2, and a drain region DE1 or DE2 (or a drain electrode). The active region AA1 or AA2 may be a region having a relatively low electrical conductivity compared to the source region SE1 or SE2 and the drain region DE1 or DE2. The source region SE1 or SE2 and the drain region DE1 or DE2 may be spaced apart from each other with the active region AA1 or AA2 interposed therebetween.

A gate electrode GE1 or GE2 may be disposed between the second insulating layer 20 and the third insulating layer 30. The gate electrode GE1 or GE2 may be disposed to overlap the active region AA1 or AA2 of the semiconductor pattern AC1 or AC2. In this embodiment, the transistor TR1 or TR2 is illustrated as having a top-gate structure. However, this is illustrated as an example, and the gate electrode GE1 or GE2 may be disposed below the semiconductor pattern AC1 or AC2.

The source region SE1 or SE2, the active region AA1 or AA2, and the drain region DE1 or DE2 of the transistor TR1 or TR2 may be covered by the second insulating layer 20. The gate electrode GE1 or GE2 in the transistor TR1 or TR2 may be covered by the third insulating layer 30.

The first capacitor CPR may be disposed on the base layer BS and below the first and second transistors TR1 and TR2. The first capacitor CPR may include a first lower capacitor electrode LCE1 and a second lower capacitor electrode LCE2. The first lower capacitor electrode LCE1 and the second lower capacitor electrode LCE2 may be disposed below the semiconductor patterns AC1 and AC2. A detailed description of the first capacitor CPR will be described later.

The first capacitor CPR may be connected to the second transistor TR2 through the upper electrode UE. The upper electrode UE may be disposed on the first capacitor CPR and the second transistor TR2. The upper electrode UE may have a bridge shape in a cross-sectional view.

The upper electrode UE may be connected to the first capacitor CPR and the second transistor TR2 through a contact hole CNT1-1 passing through the buffer layers BFL1 and BFL2, the second lower capacitor electrode LCE2, and the first to fourth insulating layers 10, 20, 30, and 40 and a contact hole CNT1-2 passing through the second to fourth insulating layers 20, 30, and 40, respectively. That is, the upper electrode UE may connect the first capacitor CPR and the second transistor TR2 to each other. The upper electrode UE may be connected to the first lower capacitor electrode LCE1 of the first capacitor CPR. The upper electrode UE may include the same material as at least one of the electrodes of the first capacitor CPR.

When the upper electrode UE is connected to the first lower capacitor electrode LCE1 of the first capacitor CPR, the distance between a transistor and a capacitor electrode connected to the transistor may increase compared to when the upper electrode UE is connected to the second lower capacitor electrode LCE2. Accordingly, electrical interference between the transistor and the first capacitor CPR may be reduced, and voltage accumulation may be stably achieved.

The first lower capacitor electrode LCE1 may be connected between the second node N2 and the data line DL (see FIG. 5). The first lower capacitor electrode LCE1 may have a shape integrated with the data line DL. That is, in an embodiment of the inventive concept, the first lower capacitor electrode LCE1 may be utilized as the data line DL. However, this is merely illustrated as an example, and the second lower capacitor electrode LCE2 may have a shape integrated with the data line DL. That is, in an embodiment of the inventive concept, the second lower capacitor electrode LCE2 may be utilized as the data line DL. Accordingly, a separate line may not be added, thus saving space in the circuit. In addition, the degree of freedom in circuit design may be increased, thereby enabling an efficient layout design. However, the embodiment of the inventive concept is not limited thereto, and the first lower capacitor electrode LCE1 may have a shape integrated with the gate line GL (see FIG. 5).

The second capacitor CST may be disposed on the base layer BS. The second capacitor CST may be disposed above the first and second transistors TR1 and TR2. The second capacitor CST may include a first upper capacitor electrode UCE1 (or a first gate electrode), a second upper capacitor electrode UCE2 (or a second gate electrode), and a third upper capacitor electrode UCE3 (or a third gate electrode). The second upper capacitor electrode UCE2 may be disposed on the first upper capacitor electrode UCE1, and the third upper capacitor electrode UCE3 may be disposed on the second upper capacitor electrode UCE2. In this case, the first upper capacitor electrode UCE1 may correspond to the first gate electrode GE1 of the first transistor TR1. That is, the first transistor TR1 and the second capacitor CST may share at least one electrode.

A capacitor CST1 may be formed by the second upper capacitor electrode UCE2 and the third upper capacitor electrode UCE3. A capacitor CST2 may be formed by the first upper capacitor electrode UCE1 and the second upper capacitor electrode UCE2. That is, the second capacitor CST may have a dual capacitor structure.

The second capacitor CST may be connected to the first transistor TR1. The third upper capacitor electrode UCE3 of the second capacitor CST may be connected to the first transistor TR1 and the second transistor TR2 through a contact hole CNT3-1 passing through the second to fourth insulating layers 20, 30, and 40 and a contact hole CNT3-2 passing through the third and fourth insulating layers 30 and 40, respectively. The first capacitor CPR may correspond to the parasitic capacitor CPR illustrated in FIG. 6, and the second capacitor CST may correspond to the storage capacitor CST illustrated in FIG. 6. However, the embodiment of the inventive concept is not limited thereto.

The first insulating layer 10 disposed between the first lower capacitor electrode LCE1 and the second lower capacitor electrode LCE2 may insulate the first lower capacitor electrode LCE1 and the second lower capacitor electrode LCE2 from each other, and function as a dielectric of the first capacitor CPR between the first lower capacitor electrode LCE1 and the second lower capacitor electrode LCE2.

The third insulating layer 30 disposed between the first upper capacitor electrode UCE1 and the second upper capacitor electrode UCE2 may insulate the first and second upper capacitor electrodes UCE1 and UCE2 from each other, and the fourth insulating layer 40 disposed between the second upper capacitor electrode UCE2 and the third upper capacitor electrode UCE3 may insulate the second and third upper capacitor electrodes UCE2 and UCE3 from each other. In addition, the third insulating layer 30 disposed between the first upper capacitor electrode UCE1 and the second upper capacitor electrode UCE2 may function as a dielectric of the second capacitor CST between the first and second upper capacitor electrodes UCE1 and UCE2, and the fourth insulating layer 40 disposed between the second upper capacitor electrode UCE2 and the third upper capacitor electrode UCE3 may function as a dielectric of the second capacitor CST between the second and third upper capacitor electrodes UCE2 and UCE3.

A first connection electrode CNa may be disposed between the third insulation layer 30 and the fourth insulation layer 40. The first connection electrode CNa may be connected to the second gate electrode GE2 through a contact hole CNT2 passing through the third insulation layer 30. A second connection electrode CNb may be connected to the first connection electrode CNa through a contact hole CNT4 passing through the fourth and fifth insulating layers 40 and 50. A third connection electrode CNc may be connected to the first semiconductor pattern AC1 through a contact hole CNT5 passing through the second to fifth insulating layers 20, 30, 40, and 50. A driving signal may be transmitted to the display element layer DP-OLED through the third connection electrode CNc.

Referring to FIG. 8, in an embodiment of the inventive concept, the display panel DP may further include a shielding electrode SSE. The shielding electrode SSE may be disposed between the first gate electrode GE1 of the first transistor TR1 and the second gate electrode GE2 of the second transistor TR2 with respect to the first direction DR1. The shielding electrode SSE may be disposed between the first gate electrode GE1 and the second gate electrode GE2 to perform a shielding function.

The display element layer DP-OLED may be disposed on the circuit element layer DP-CL. The display element layer DP-OLED may include a pixel defining film PDL and a light-emitting element OLED.

The pixel defining film PDL may be disposed on the sixth insulating layer 60 of the circuit element layer DP-CL. A light-emitting opening PDL-OP may be defined in the pixel defining film PDL. That is, the pixel defining film PDL may have a light-emitting opening PDL-OP. The light-emitting opening PDL-OP may correspond to the anode AE, and the pixel defining film PDL may expose at least a portion of the anode AE through the light-emitting opening PDL-OP.

The pixel defining film PDL may include an inorganic insulating material. For example, the pixel defining film PDL may include silicon nitride (SiNx) (or silicon nitride).

The light-emitting element OLED may include an anode AE, a light-emitting layer EML, and a cathode CE.

The anode AE may be disposed on the sixth insulating layer 60 of the circuit element layer DP-CL. The anode AE may be a transmissive electrode, a semi-transmissive electrode, or a reflective electrode. The anode AE may include a single-layer or multi-layer structure. The anode AE may include a plurality of layers including ITO and Ag. For example, the anode AE may include a layer including ITO (hereinafter, a lower ITO layer), a layer including Ag disposed on the lower ITO layer (hereinafter, an Ag layer), and a layer including ITO disposed on the Ag layer (hereinafter, an upper ITO layer). Without being limited thereto, however, the anode AE may be provided as a single layer.

A light-emitting layer EML may be disposed on the anode AE. The light-emitting layer EML may also be referred to as an ‘organic layer’ or an ‘intermediate layer’. The light-emitting layer EML may cover a portion of the upper surface of the pixel defining film PDL.

The light-emitting element OLED may further include a hole control layer HCL, which may include a hole injection layer (HIL) and a hole transport layer (HTL) disposed between the anode AE and the light-emitting layer EML, and may further include an electron control layer ECL, which may include an electron transport layer ETL and an electron injection layer (EIL) disposed on the light-emitting layer (EML).

The cathode CE may be disposed on the light-emitting layer EML. The cathode CE may cover the light-emitting layer EML. The cathode CE may be disposed on an electron control layer ECL. The cathode CE may be commonly disposed in the pixels PX (see FIG. 5). That is, the cathode CE may be commonly disposed on the light-emitting layers EML of the pixels PX.

The thin film encapsulation layer TFE may be disposed on the light-emitting element OLED. The thin film encapsulation layer TFE may include an inorganic layer, an organic layer, and an inorganic layer that are sequentially stacked. The inorganic layers may include an inorganic material and protect the pixels PX from moisture/oxygen. The organic layer may include an organic material and protect the pixels PX from foreign substances such as dust particles.

According to an embodiment of the inventive concept, the first capacitor CPR may be disposed below the first and second transistors TR1 and TR2. The first capacitor CPR may be a parasitic capacitor formed between the second node N2 (see FIG. 6) and the data line DL (see FIG. 6). That is, the first capacitor CPR may include a first lower capacitor electrode LCE1 connected to the data line and a second lower capacitor electrode LCE2 connected to the second node N2. In this embodiment, the second lower capacitor electrode LCE2 may be disposed on the first lower capacitor electrode LCE1. However, this is merely illustrated as an example, and the first lower capacitor electrode LCE1 may also be disposed on the second lower capacitor electrode LCE2, and the inventive concept is not limited to any one embodiment.

According to the present invention, since the first capacitor CPR is disposed below the first and second transistors TR1 and TR2, the first capacitor CPR may be disposed on a layer different from that of the second capacitor CST with the first and second transistors TR1 and TR2 interposed therebetween. As the first capacitor CPR is not affected by the electrodes of the transistors and the design of the lines connected thereto when the first capacitor CPR is formed, the areas of the first lower capacitor electrode LCE1 and the second lower capacitor electrode LCE2 of the first capacitor CPR may be easily secured. Accordingly, interference with other components included in the pixel driver of each of the pixels PX may be prevented, and the capacitance of the first capacitor CPR may be sufficiently secured without increasing the area occupied by the pixel driver. Therefore, a greater number of pixels may be disposed within a certain area, and an electronic apparatus with increased resolution may be provided. In other words, design flexibility for the capacitor and the pixel driver may be increased, the process may be simplified, and the integration density of the source and drain electrodes may be reduced.

In this case, the area occupied by each of the first lower capacitor electrode LCE1 and the second lower capacitor electrode LCE2 of the first capacitor CPR may be larger than the area occupied by the anode AE. The ratio between the area occupied by each of the first and second lower capacitor electrodes LCE1 and LCE2 and the area occupied by the anode AE may be 1.4 or more. The area of each of the first and second lower capacitor electrodes LCE1 and LCE2 may be 140% or more of the area of the anode AE. By forming the area of each electrode of the first capacitor CPR to be larger than that of the anode AE, current and voltage changes caused by a driving signal may be absorbed or mitigated by the capacitor. Accordingly, signal fluctuations may be minimized, thus enabling stable pixel driving. In addition, increasing the area of the electrodes of the first capacitor CPR may reduce interference between adjacent pixels PX or circuits. While the anode AE is driven, the first capacitor CPR may maintain a stable voltage, enabling clearer and more accurate image expression in a high-resolution electronic apparatus.

The first capacitor CPR and the second capacitor CST may be respectively placed below and above the first and second transistors TR1 and TR2. Accordingly, compared to a case in which all of the capacitors CPR and CST are disposed above the transistors TR1 and TR2, spatial constraints in forming the electrodes of the capacitors CPR and CST may be reduced. That is, since the areas occupied by the electrodes of the capacitors CPR and CST are efficiently distributed, available space for disposing other elements or lines within the circuit may be secured.

In addition, since the first capacitor CPR and the second capacitor CST are respectively arranged below and above the first and second transistors TR1 and TR2, the source electrode and drain electrode of each of the transistors TR1 and TR2 may be disposed in different layers. Accordingly, since current flows through various paths, resistance may be distributed, and drain-source resistance (D/R) may be alleviated.

In addition, compared to a case in which each of the capacitors CPR and CST is disposed above the transistors TR1 and TR2, the number of layers stacked on the transistors TR1 and TR2 may be reduced. That is, a spacing distance SD from the semiconductor patterns AC1 and AC2 of the transistors TR1 and TR2 to the anode AE may be reduced. Specifically, referring to FIG. 8, the spacing distance SD from the first semiconductor pattern AC1 to the anode AE may be 1.5 μm or less.

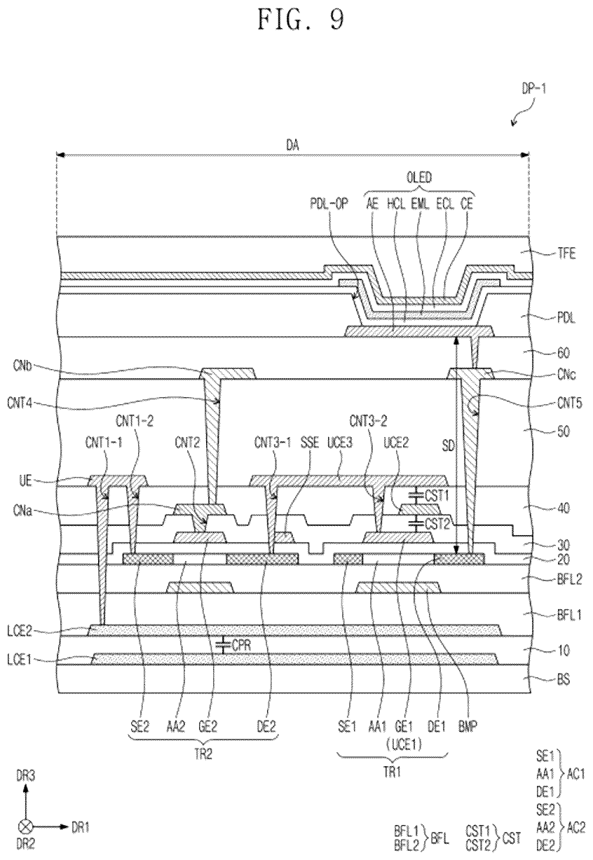

FIG. 9 is a cross-sectional view of a display panel taken along a line I-I′ of FIG. 5. In the following description with reference to FIG. 9, the same/similar reference numerals will be used for the same/similar components as those described in FIG. 8, and duplicate descriptions will be omitted.

Referring to FIG. 9, in the display panel DP-1, the first capacitor CPR may be connected to the second transistor TR2 through the upper electrode UE. The upper electrode UE may be disposed on the first capacitor CPR and the second transistor TR2. The upper electrode UE may have a bridge shape in a cross-sectional view.

The upper electrode UE may be connected to the first capacitor CPR and the second transistor TR2 through the contact hole CNT1-1 passing through the buffer layers BFL1 and BFL2 and second to fourth insulating layers 20, 30, and 40 and the contact hole CNT1-2 passing through the second to fourth insulating layers 20, 30, and 40, respectively. That is, the upper electrode UE may connect the first capacitor CPR and the second transistor TR2 to each other. The upper electrode UE may be connected to the second lower capacitor electrode LCE2 of the first capacitor CPR. The upper electrode UE may include the same material as at least one of the electrodes included in the first capacitor CPR.

When the upper electrode UE is connected to the second lower capacitor electrode LCE2 of the first capacitor CPR, the distance between a transistor and the capacitor electrode connected to the transistor may be reduced compared to when the upper electrode UE is connected to the first lower capacitor electrode LCE1. Accordingly, an electrical change occurring in the transistor may be transmitted to the capacitor at a faster speed, and the switching speed, accuracy, and power efficiency of the circuit may be improved.

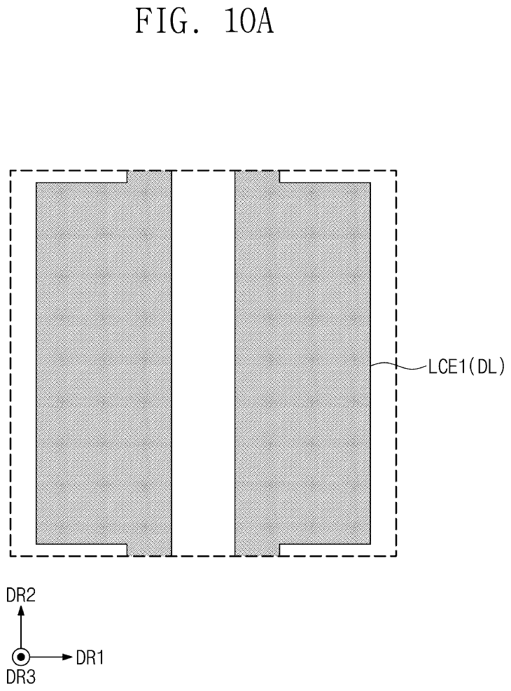

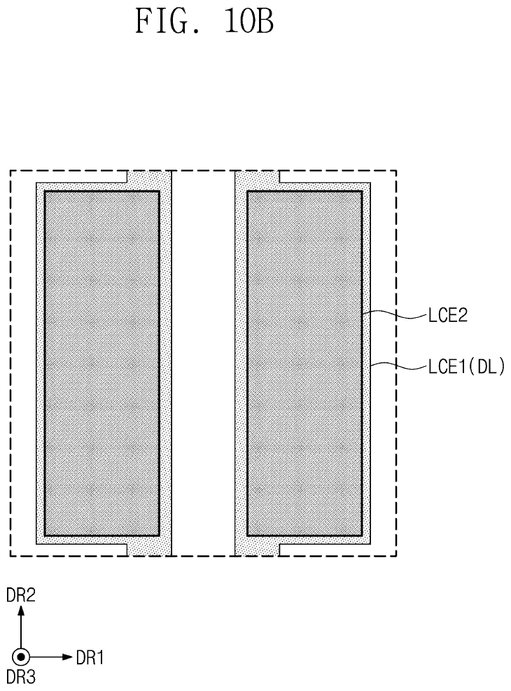

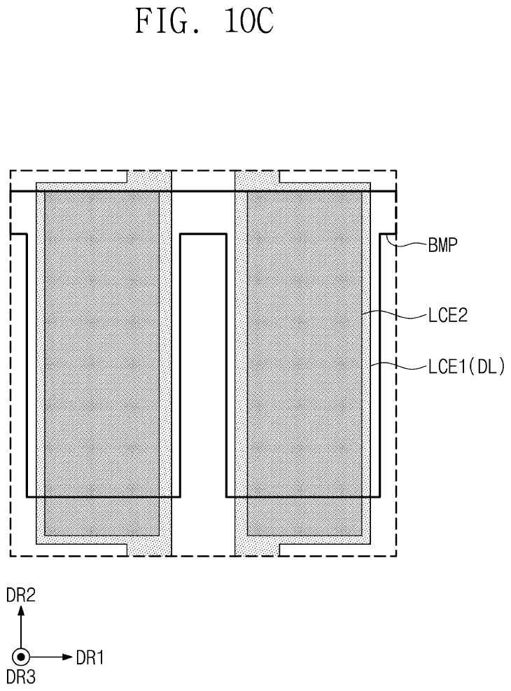

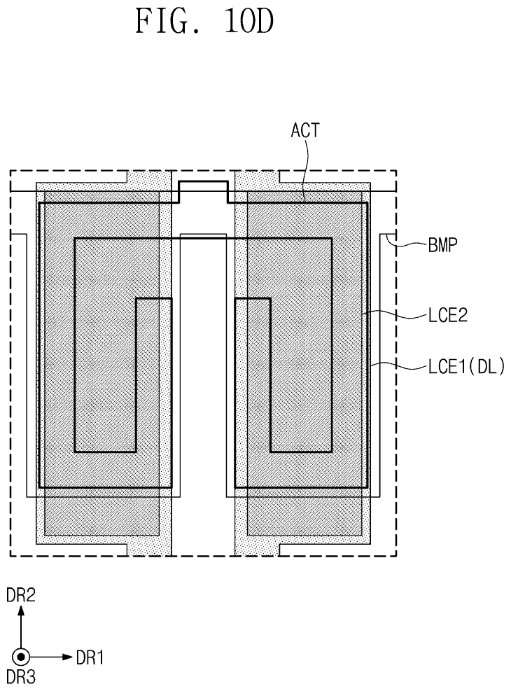

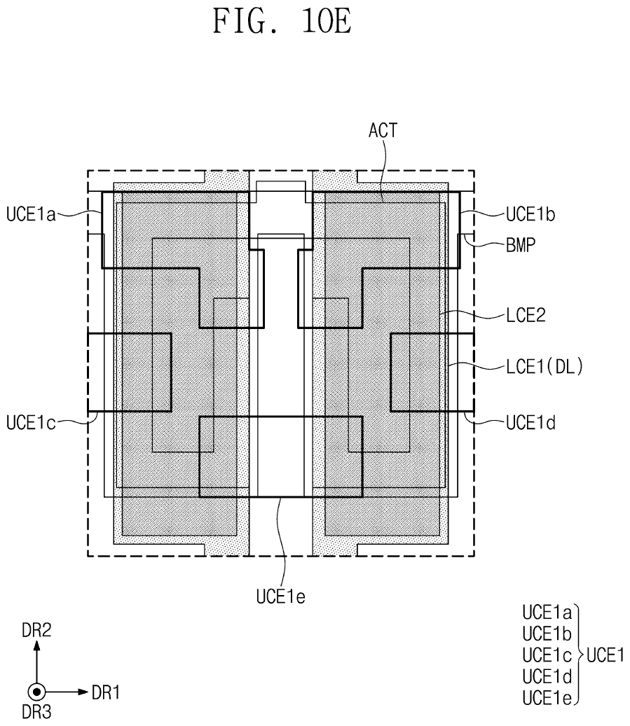

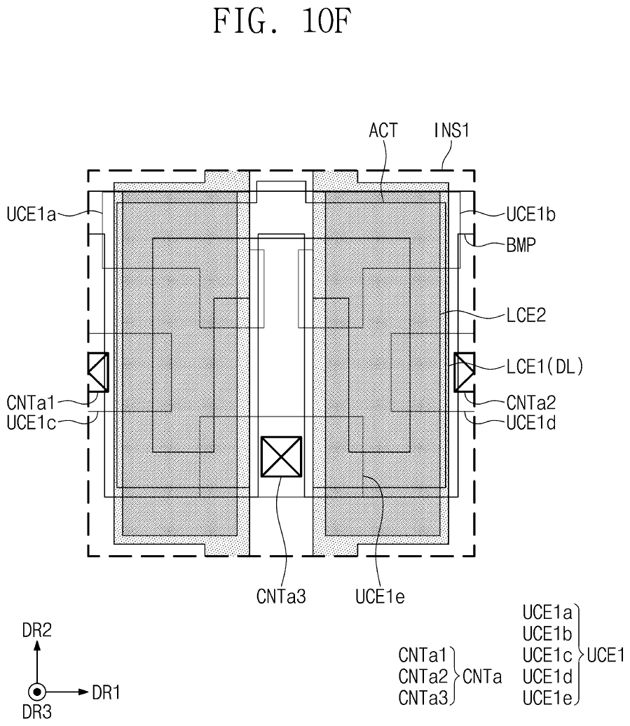

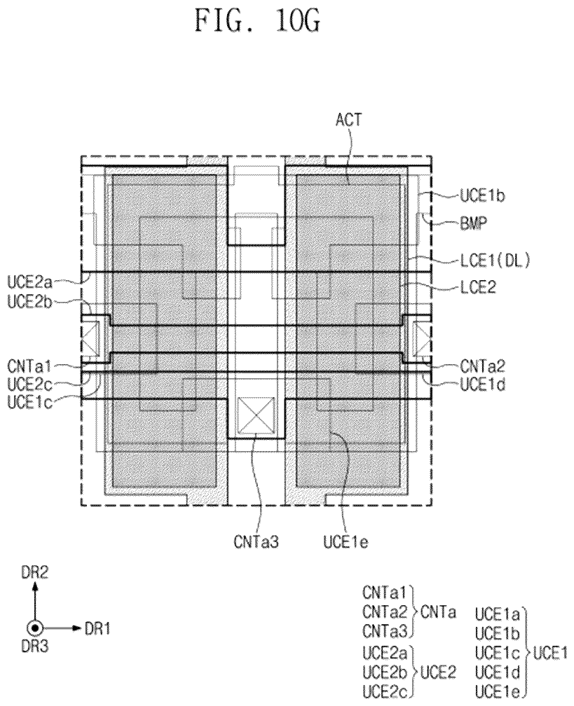

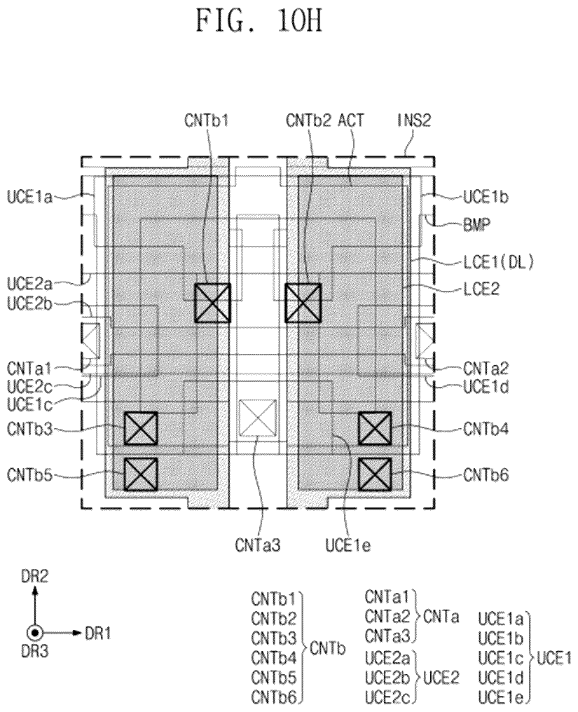

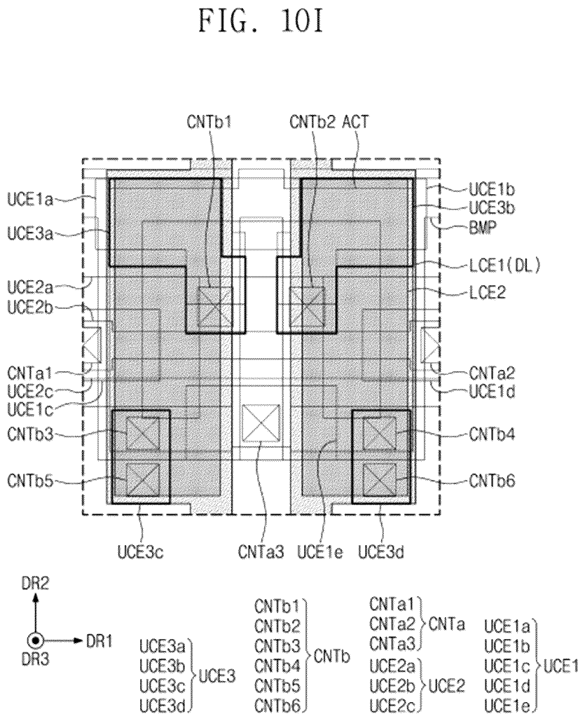

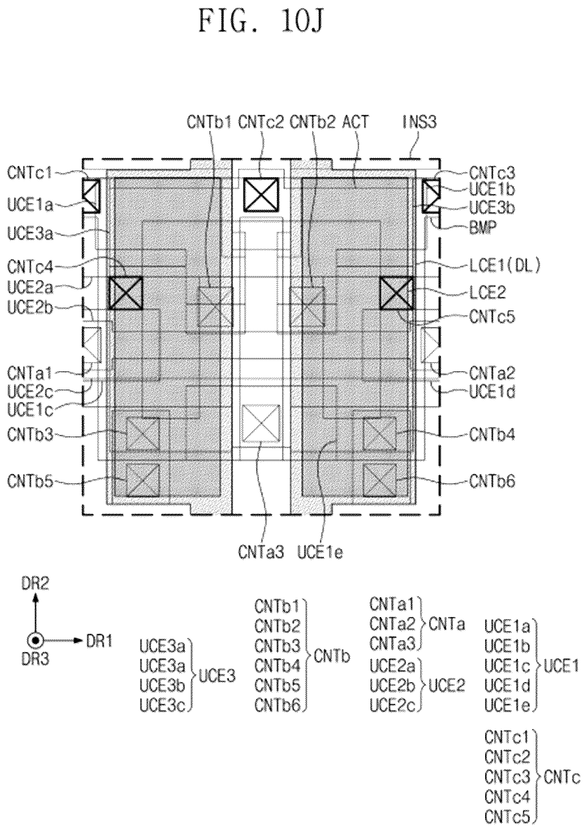

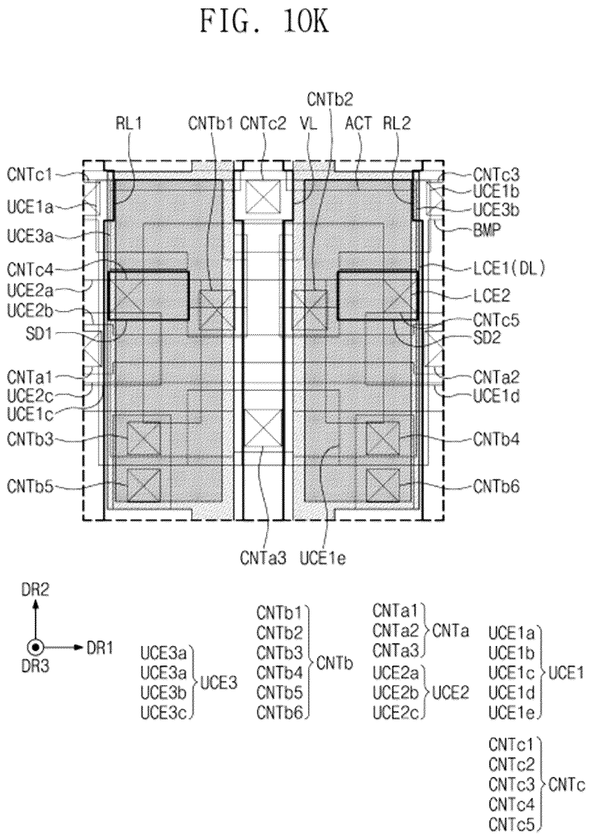

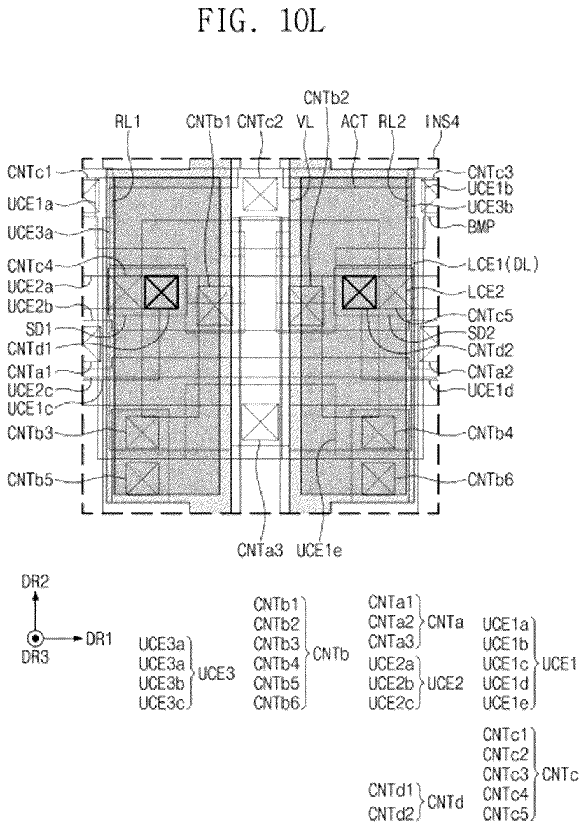

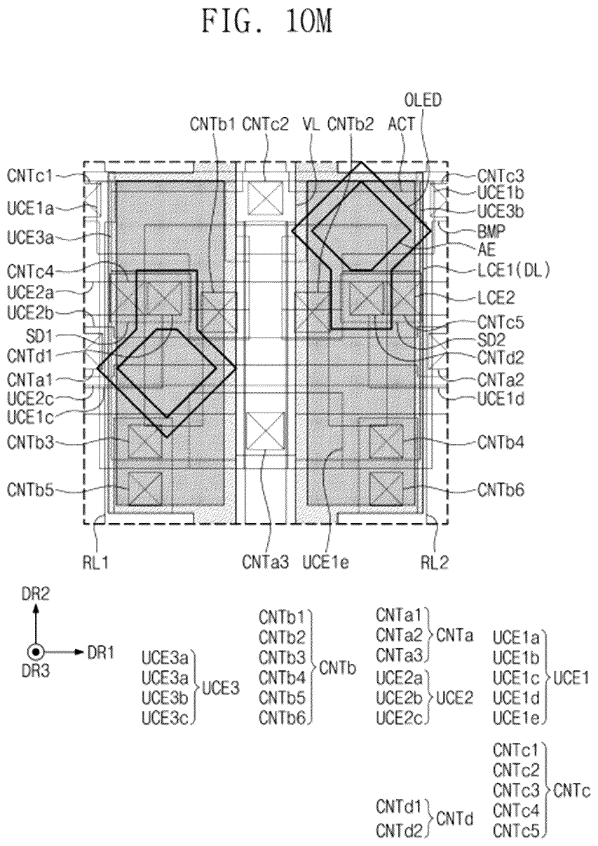

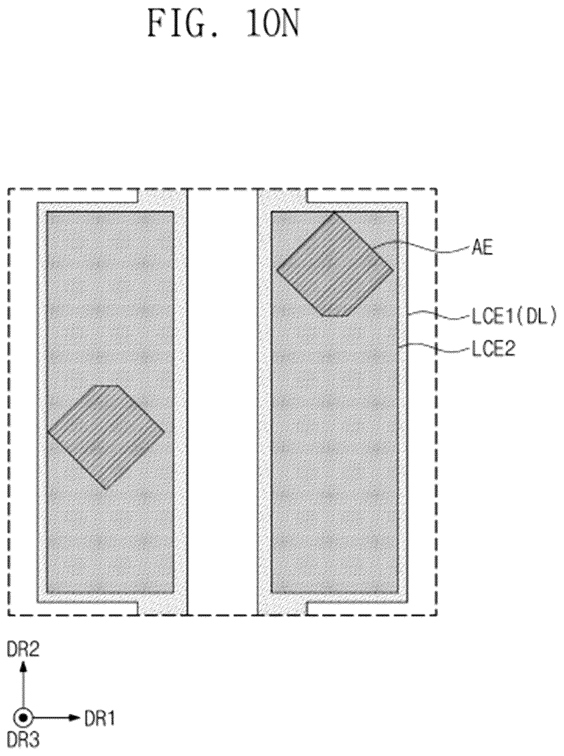

FIGS. 10A to 10N are plan views illustrating a portion of the display panel according to an embodiment of the inventive concept.

Referring to FIGS. 10A and 10B, the second lower capacitor electrode LCE2 may be disposed on the first lower capacitor electrode LCE1. The second lower capacitor electrode LCE2 may overlap the first lower capacitor electrode LCE1 on a plane. The first lower capacitor electrode LCE1 may form the first capacitor CPR (see FIG. 8) together with the second lower capacitor electrode LCE2.

The first lower capacitor electrode LCE1 may have a shape integrated with the data line DL. That is, in an embodiment of the inventive concept, the first lower capacitor electrode LCE1 may be utilized as the data line DL. Accordingly, a separate line may not be added, and space in the circuit may be saved. In addition, the degree of freedom in circuit design may be increased, thus enabling efficient layout design. However, the embodiment of the inventive concept is not limited thereto, and the first lower capacitor electrode LCE1 may have a shape integrated with the gate line GL (see FIG. 5).

According to an embodiment of the inventive concept, the data line DL may include a line portion extending in the second direction DR2 and a portion protruding from the line portion. In this case, the line portion may be insulated from and cross the gate line GL (see FIG. 5). The second lower capacitor electrode LCE2 may overlap the protruding portion of the data line on a plane. That is, the protruding portion of the data line DL may form a capacitor together with the second lower capacitor electrode LCE2. The protruding portion of the data line DL may overlap the anode AE on a plane. In this case, the area occupied by each of the protruding portion and the second lower capacitor electrode LCE2 may be larger than the area occupied by the anode AE.

Although FIGS. 10A and 10B illustrate that the first lower capacitor electrode LCE1 has a shape integrated with the data line DL, the embodiment of the inventive concept is not limited thereto. For example, the second lower capacitor electrode LCE2 disposed on the first lower capacitor electrode LCE1 may have a shape integrated with the data line DL and form a capacitor together with the first lower capacitor electrode LCE1.

Referring to FIG. 10C, the lower conductive pattern BMP may be disposed above the lower capacitor electrodes LCE1 and LCE2. The lower conductive pattern BMP may overlap the lower capacitor electrodes LCE1 and LCE2 on a plane.

Referring to FIG. 10D, an active layer ACT of a transistor may be disposed on the lower conductive pattern BMP. The active layer ACT may correspond to a layer in which the first and second semiconductor patterns AC1 and AC2 illustrated in FIG. 8 are disposed. The active layer ACT may overlap the lower conductive pattern BMP on a plane. By placing the lower conductive pattern BMP to overlap the active layer ACT of each of the transistors, electrical interference on the transistors from the conductive layers disposed below the transistors may be minimized.

Referring to FIGS. 10E to 10J, on the active layer ACT, gate electrodes UCE1, UCE2, and UCE3 may be disposed and contact holes CNTa, CNTb, and CNTc configured to connect the gate electrodes UCE1, UCE2, and UCE3 and other conductive layers to each other may be defined. In this case, the gate electrodes UCE1, UCE2, and UCE3 may correspond to the first to third upper capacitor electrodes UCE1, UCE2, and UCE3 illustrated in FIG. 8, and the contact holes CNTa, CNTb, and CNTc may correspond to the contact holes CNT1-1 to CNT5 illustrated in FIG. 8.

Referring to FIG. 10F, among the contact holes CNTa, CNTb, and CNTc, a first contact hole CNTa may be formed by passing through an insulating layer INS1 formed on the first gate electrode UCE1. In this case, the insulating layer INS1 may correspond to the third insulating layer 30 illustrated in FIG. 8, and the first contact hole CNTa may correspond to the contact hole CNT2 passing through the third insulating layer 30 illustrated in FIG. 8.

Referring to FIG. 10H, among the contact holes CNTa, CNTb, and CNTc, a second contact hole CNTb may be formed by passing through an insulating layer INS2 formed on the second gate electrode UCE2. In this case, the insulating layer INS2 may correspond to the fourth insulating layer 40 of FIG. 8, and the second contact hole CNTb may correspond to the contact holes CNT1-1, CNT1-2, CNT3-1, and CNT3-2 passing through the fourth insulating layer 40 of FIG. 8.

Referring to FIG. 10J, among the contact holes CNTa, CNTb, and CNTc, a third contact hole CNTc may be formed by passing through an insulating layer INS3 formed on the third gate electrode UCE3. In this case, the insulating layer INS3 may correspond to the fifth insulating layer 50 of FIG. 8, and the third contact hole CNTc may correspond to the contact holes CNT4 and CNT5 passing through the fifth insulating layer 50 of FIG. 8.

Referring to FIGS. 10K and 10L, on the gate electrodes UCE1, UCE2, and UCE3, a driving voltage line VL, initialization voltage lines RL1 and RL2, and connection electrodes SD1 and SD2 may be disposed and a contact hole CNTd configured to connect the connection electrodes SD1 and SD2 to the light-emitting element OLED may be defined. The driving voltage line VL may correspond to the first power line PL1 illustrated in FIG. 6, the initialization voltage lines RL1 and RL2 may correspond to the initialization line VIL illustrated in FIG. 6, and the connection electrodes SD1 and SD2 may correspond to the connection electrode CNc illustrated in FIG. 8.

Referring to FIG. 10L, the contact hole CNTd may be formed by passing through an insulating layer INS4 formed on the driving voltage line VL, the initialization voltage lines RL1 and RL2, and the connection electrodes SD1 and SD2. In this case, the insulating layer INS4 may correspond to the sixth insulating layer 60 of FIG. 8, and the contact hole CNTd may correspond to a contact hole passing through the sixth insulating layer 60, which connects the anode AE to the third connection electrode CNc, of FIG. 8.

Referring to FIG. 10M, the light-emitting elements OLED including an anode AE may be disposed on the driving voltage line VL, the initialization voltage lines RL1 and RL2, and the connection electrodes SD1 and SD2. The light-emitting element OLED may be connected to the connection electrodes SD1 and SD2 through the contact hole CNTd.

Referring to FIG. 10N, the anode AE may overlap the first and second lower capacitor electrodes LCE1 and LCE2 on a plane. In this case, the area occupied by each of the first and second lower capacitor electrodes LCE1 and LCE2 may be larger than the area occupied by the anode AE. The ratio between the area occupied by each of the first and second lower capacitor electrodes LCE1 and LCE2 and the area occupied by the anode AE may be 1.4 or more. The area of each of the first and second lower capacitor electrodes LCE1 and LCE2 may be 140% or more of the area of the anode AE. By forming the area of each of the electrodes of the first capacitor CPR to be larger than that of the anode AE, current and voltage changes caused by a driving signal may be absorbed or mitigated by the capacitor. Accordingly, signal fluctuations may be minimized, thus enabling stable pixel driving. In addition, increasing the electrode area of the first capacitor CPR may reduce interference between adjacent pixels or circuits. While the anode AE is driven, the parasitic capacitor may maintain a stable voltage, enabling clearer and more accurate image expression in a high-resolution electronic apparatus.

As described above, by placing the first capacitor CPR below the first and second transistors TR1 and TR2, the formation of the first capacitor CPR may not be affected by the electrodes of the transistors and the design of the lines connected thereto. Accordingly, the areas of the first lower capacitor electrode LCE1 and the second lower capacitor electrode LCE2 of the first capacitor CPR may be easily secured.

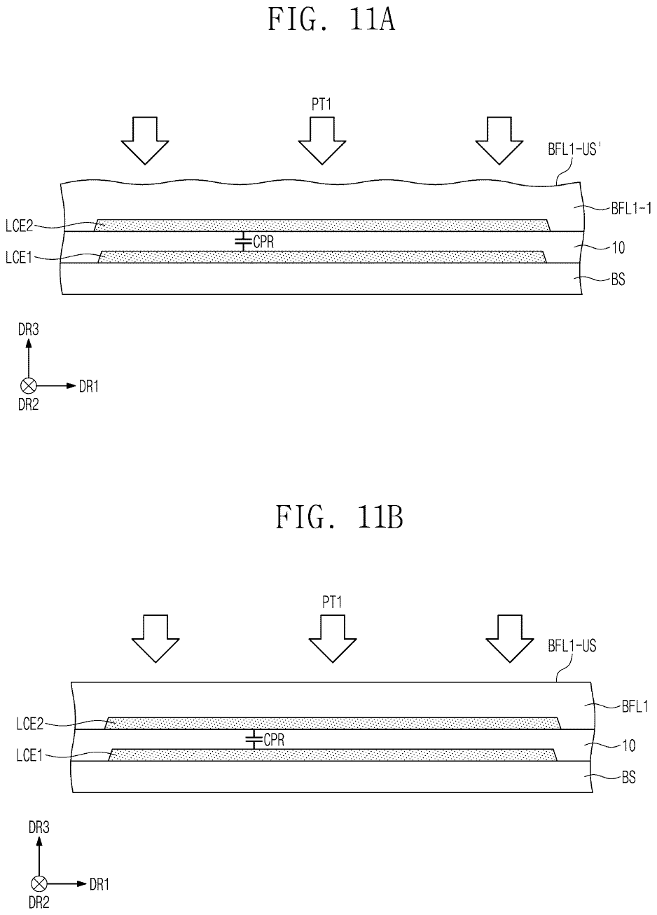

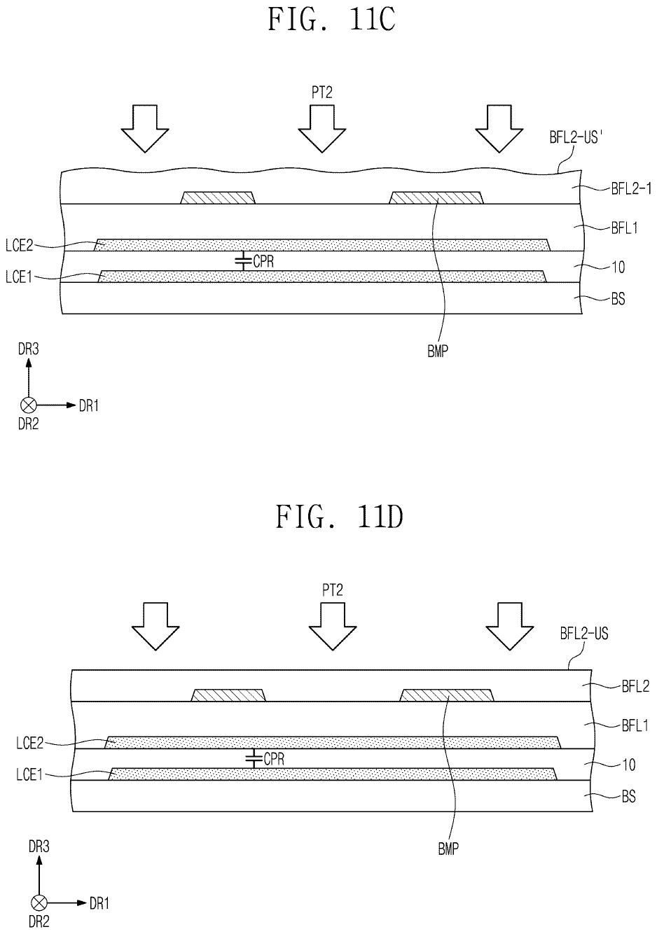

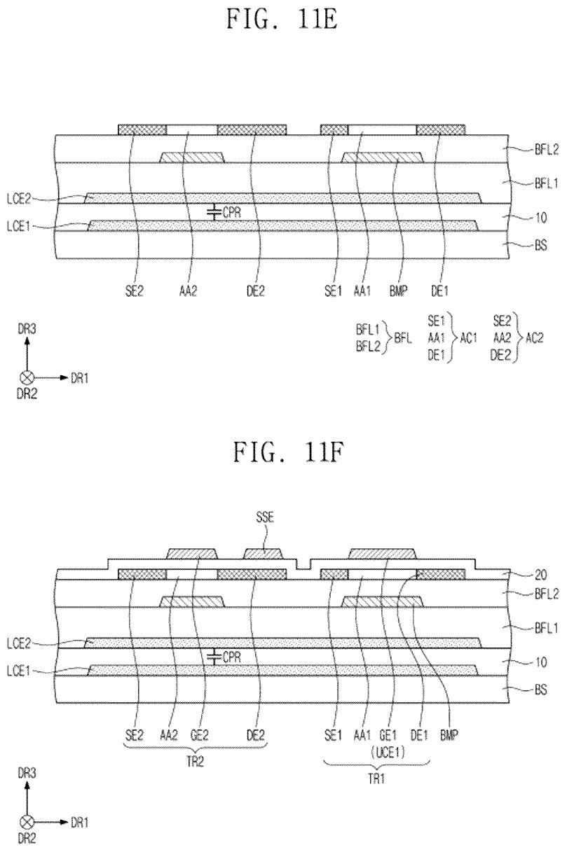

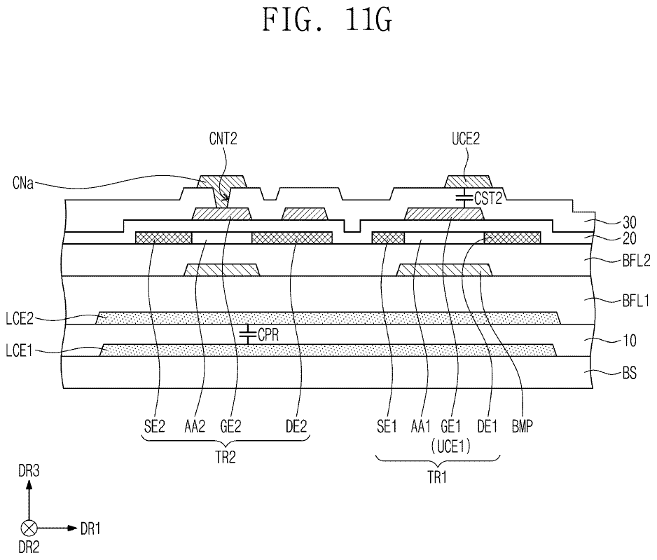

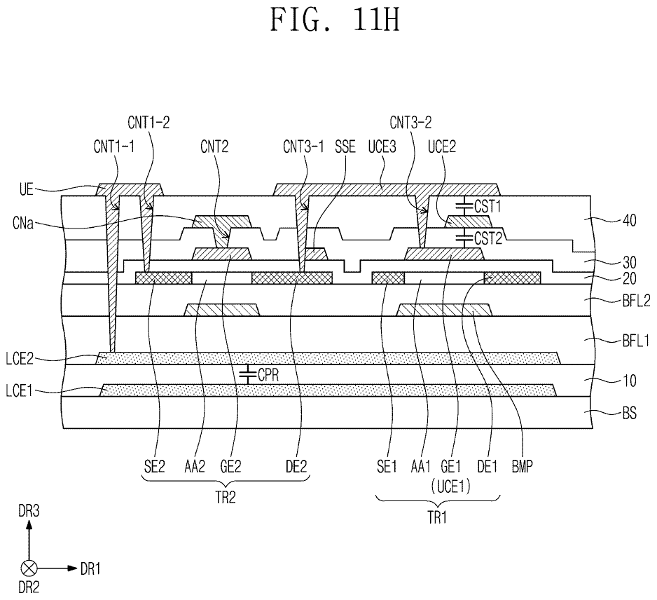

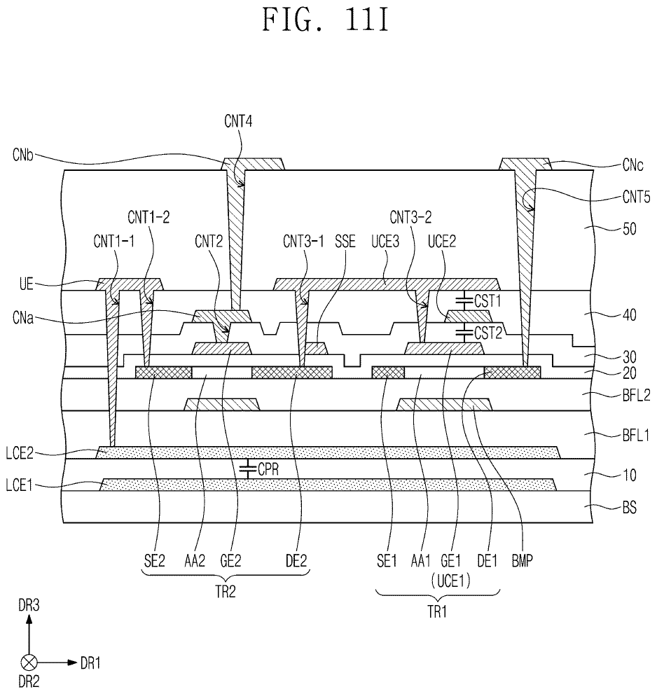

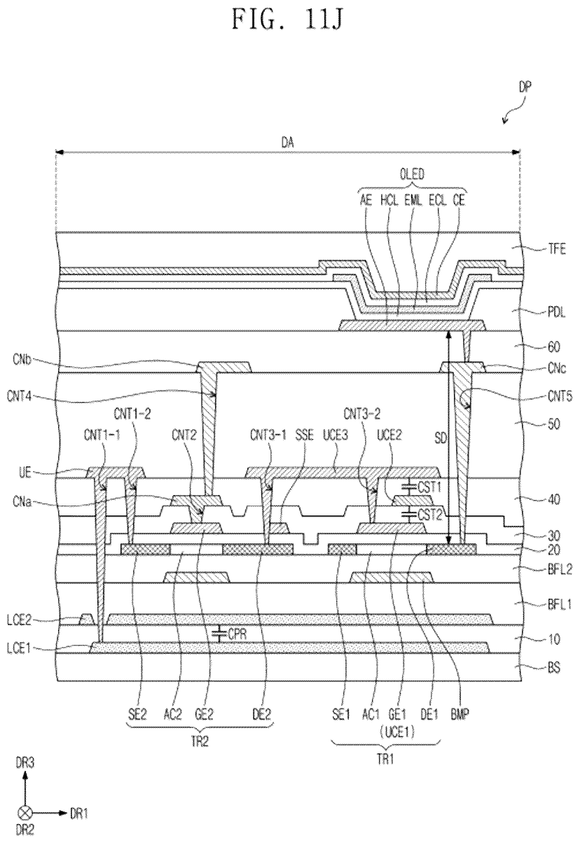

FIGS. 11A to 11J are cross-sectional views illustrating some steps of a method for manufacturing the display panel according to an embodiment of the inventive concept. Hereinafter, in the description with reference to FIGS. 11A to 11J, the same/similar reference numerals will be used for the same/similar components as those described in FIGS. 9 to 10M, and duplicate descriptions will be omitted.

Referring to FIGS. 11A and 11B, a first preliminary buffer layer BFL1-1 may be formed on and cover the second lower capacitor electrode LCE2. An upper surface BFL1-US′ of the formed first preliminary buffer layer BFL1-1 may not be flat. For example, the short-range surface roughness of the upper surface BFL1-US′ of the first preliminary buffer layer BFL1-1 may be 10 nm or more, and the long-range surface roughness thereof may be 200 nm or more. In this specification, the short-range surface roughness may mean a surface roughness measured when the length scale is less than 1 μm, and the long-range surface roughness may mean a surface roughness measured when the length scale is 1 μm or more.

The method of manufacturing the display panel according to an embodiment of the inventive concept may include polishing the upper surface BFL1-US′ of the first preliminary buffer layer BFL1-1 after the forming of the first preliminary buffer layer BFL1-1. The polishing of the upper surface BFL1-US′ of the first preliminary buffer layer BFL1-1 may include a chemical mechanical polishing (CMP) process. In this specification, polishing may comprehensively mean performing a process for making the surface of the upper surface BFL1-US′ of the first preliminary buffer layer BFL1-1 smoother. A polishing solution PT1 (or polishing gas) may be applied onto the first preliminary buffer layer BFL1-1 to planarize the upper surface BFL1-US'. In this case, the polishing solution PT1 may contain a slurry.

The polishing solution PT1 may be provided onto the upper surface BFL1-US′ of the first preliminary buffer layer BFL1-1 so that a chemical reaction may occur to polish and planarize the upper surface BFL1-US′ of the first preliminary buffer layer BFL1-1. In addition, in this case, although not illustrated, a polishing pad may be utilized together to planarize the upper surface BFL1-US′ of the first preliminary buffer layer BFL1-1. When the polishing pad applies pressure to the upper surface BFL1-US′ of the first preliminary buffer layer BFL1-1 to cause friction, the upper surface BFL1-US′ of the first preliminary buffer layer BFL1-1 may be planarized.

Through the polishing of the upper surface BFL1-US′ of the first preliminary buffer layer BFL1-1, a first buffer layer BFL1 having a planarized upper surface BFL1-US may be formed. For example, the short-range surface roughness of the first buffer layer BFL1 may be less than 10 nm, and the long-range surface roughness thereof may be less than 200 nm. As the first buffer layer BFL1 having the planarized upper surface BFL1-US is formed through a planarization process and a lower conductive pattern BMP is formed on the planarized first buffer layer BFL1, the lower conductive pattern BMP may be formed more uniformly and accurately. In addition, the possibility of defects occurring in a subsequent process step may be reduced. However, this is described as an example, and as long as the first buffer layer BFL1 having the planarized upper surface BFL1-US can be formed, the method of manufacturing the display panel DP according to an embodiment of the inventive concept may include various process steps and is not limited to any one embodiment.

Referring to FIG. 11C and FIG. 11D, a lower conductive pattern BMP may be formed on the first buffer layer BFL1, and a second preliminary buffer layer BFL2-1 may be formed on and cover the lower conductive pattern BMP. An upper surface BFL2-US′ of the formed second preliminary buffer layer BFL2-1 may not be flat. For example, the short-range surface roughness of the upper surface BFL2-US′ of the second preliminary buffer layer BFL2-1 may be 10 nm or more, and the long-range surface roughness thereof may be 200 nm or more.

The method of manufacturing the display panel according to an embodiment of the inventive concept may include polishing the upper surface BFL2-US′ of the second preliminary buffer layer BFL2-1 after forming the second preliminary buffer layer BFL2-1. The polishing of the upper surface BFL2-US′ of the second preliminary buffer layer BFL2-1 may include a chemical mechanical polishing (CMP) process. The upper surface BFL2-US′ of the second preliminary buffer layer BFL2-1 may be planarized by applying a polishing solution PT2.

Through the polishing of the upper surface BFL2-US′ of the second preliminary buffer layer BFL2-1, a second buffer layer BFL2 having a planarized upper surface BFL2-US may be formed. For example, the short-range surface roughness of the second buffer layer BFL2 may be less than 10 nm, and the long-range surface roughness thereof may be less than 200 nm. As the second buffer layer BFL2 having the planarized upper surface BFL2-US is formed through a planarization process and the semiconductor patterns of transistors are formed on the planarized second buffer layer BFL2, the semiconductor patterns may be formed more uniformly and accurately. Accordingly, the deterioration of the element characteristics of the transistors may be prevented. In addition, the possibility of defects occurring in a subsequent process step may be reduced. However, this is described as an example, and as long as the second buffer layer BFL2 having a planarized upper surface BFL2-US can be formed, the method of manufacturing the display panel DP according to an embodiment of the inventive concept may include various process steps and is not limited to any one embodiment.

Referring to FIG. 11E, semiconductor patterns AC1 and AC2 may be formed on the buffer layer BFL. The semiconductor patterns AC1 and AC2 may be formed by depositing or coating a semiconductor material on the buffer layer BFL and then patterning it into a plurality of patterns. The semiconductor patterns AC1 and AC2 may be formed in a region overlapping the lower conductive patterns BMP.

Referring to FIG. 11F, a second insulating layer 20, first and second gate electrodes GE1 and GE2, and a shielding electrode SSE may be formed on the semiconductor patterns AC1 and AC2. The second insulating layer 20 may be formed by depositing or coating an insulating material on the semiconductor patterns AC1 and AC2. Hereafter, a conductive layer may be formed by depositing or coating a conductive material on the second insulating layer 20. Hereafter, the conductive layer may be patterned to form the first and second gate electrodes GE1 and GE2 and the shielding electrode SSE. In this case, partial regions of the semiconductor patterns AC1 and AC2 may be formed as a source region SE1 or SE2 and a drain region DE1 or DE2. Accordingly, the boundaries of the source and drain regions of the semiconductor patterns AC1 and AC2 may be self-aligned by the gate electrodes GE1 and GE2.

Referring to FIG. 11G, a third insulating layer 30 may be formed on the first and second gates GE1 and GE2 and the shielding electrode SSE, and a connection electrode CNa and one of upper capacitor electrodes (or a second upper capacitor electrode UCE2) may be formed on the third insulating layer 30. The third insulating layer 30 may be formed by depositing or coating an insulating material on the first and second gates GE1 and GE2 and the shielding electrode SSE. Hereafter, a contact hole CNT2 may be formed in the third insulating layer 30. The first connection electrode CNa and the second upper capacitor electrode UCE2 may be formed by depositing or coating a conductive material on the third insulating layer 30 to form a conductive layer and then patterning the conductive layer. The first connection electrode CNa may be filled in the contact hole CNT2 and connected to the second transistor TR2.

Hereafter, referring to FIG. 11H, a fourth insulating layer 40 may be formed on the first connection electrode CNa and the second upper capacitor electrode UCE2, and an upper electrode UE and another one of the upper capacitor electrodes (or a third upper capacitor electrode UCE3) may be formed on the fourth insulating layer 40. The fourth insulating layer 40 may be formed by depositing or coating an insulating material on the first connection electrode CNa and the second upper capacitor electrode UCE2. Hereafter, a plurality of contact holes CNT1-1, CNT1-2, CNT3-1, and CNT3-2 may be formed in the first buffer layer BFL1, the second buffer layer BFL2, the second insulating layer 20 the third insulating layer 30 and/or the fourth insulating layer 40. The upper electrode UE and the third upper capacitor electrode UCE3 may be formed by depositing or coating a conductive material on the fourth insulating layer 40 to form a conductive layer and then patterning the conductive layer. The upper electrode UE and the third upper capacitor electrode UCE3 may be filled in the contact holes CNT1-1, CNT1-2, CNT3-1, and CNT3-2 and connected to the first and second transistors TR1 and TR2, respectively.

Hereafter, referring to FIG. 11I, a fifth insulating layer 50 and connection electrodes CNb and CNc may be formed on the upper electrode UE and the third upper capacitor electrode UCE3. The fifth insulating layer 50 may be formed by depositing or coating an insulating material on the upper electrode UE and the third upper capacitor electrode UCE3. Hereafter, a plurality of contact holes CNT4 and CNT5 may be formed in the second insulating layer 20, the third insulating layer 30, the fourth insulating layer 40 and/or the fifth insulating layer 50. The connection electrodes CNb and CNc may be filled in the contact holes CNT4 and CNT5 and connected to the first and second transistors TR1 and TR2, respectively.

Referring to FIG. 11J, a display element layer DP-OLED may be formed by forming a light-emitting element OLED on a sixth insulating layer 60. An anode AE may be formed by depositing a conductive material to form a conductive layer and then patterning the conductive layer. Hereafter, an insulating material layer may be formed by depositing or coating an insulating material on the anode AE, and an opening may be formed so as to form the pixel defining film PDL. Hereafter, a light-emitting layer EML and a cathode CE may be sequentially formed to form a light-emitting element OLED.

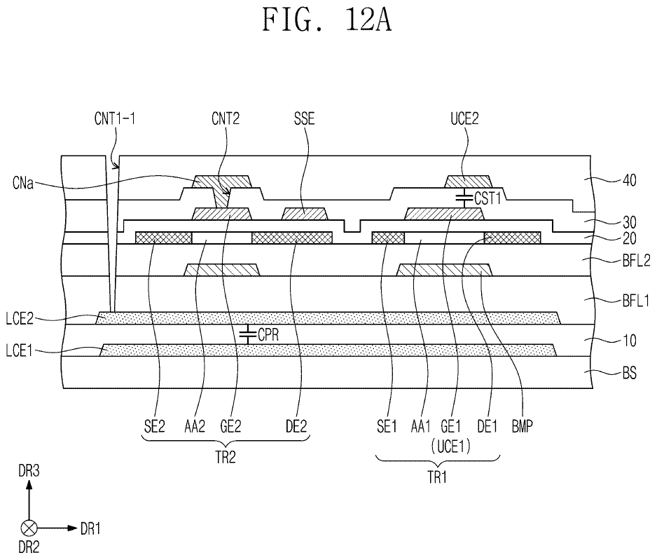

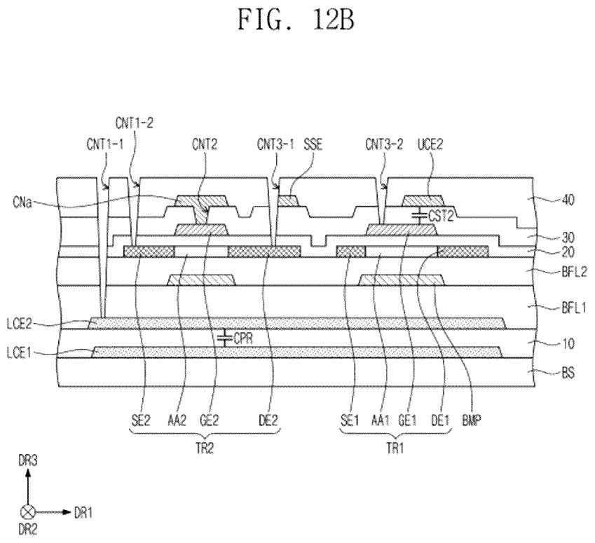

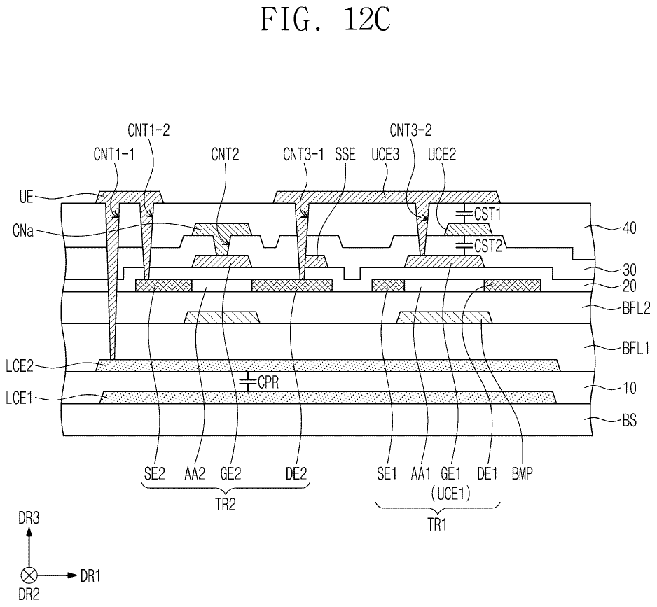

FIGS. 12A to 12C are cross-sectional views illustrating some steps of the method of manufacturing the display panel according to an embodiment of the inventive concept. In the following description with reference to FIGS. 12A to 12C, the same/similar reference numerals will be used for the same/similar components as those described in FIGS. 9 to 11J, and duplicate descriptions will be omitted.

Referring to FIGS. 12A and 12B, a single contact hole CNT1-1 may be formed by passing through the buffer layers BFL1 and BFL2 and the second to fourth insulating layers 20, 30, and 40. Hereafter, a plurality of contact holes CNT1-2 and CNT3-1 passing through the second to fourth insulating layers 20, 30, and 40 and a contact hole CNT3-2 passing through the third and fourth insulating layers 30 and 40 may be formed. That is, the relatively deep contact hole CNT1-1 may be formed first, and then the shallow contact holes CNT1-2, CNT3-1, and CNT3-2 may be additionally formed. In this case, the depth of each of the contact holes CNT1-1 to CNT3-2 may be controlled more precisely, thereby reducing errors that may occur during processing. In addition, process efficiency may be improved by applying different optimized processing conditions according to the depth of each of the contact holes CNT1-1 to CNT3-2.

Hereafter, referring to FIG. 12C, an upper electrode UE and a third upper capacitor electrode UCE3 may be formed by depositing or coating a conductive material on the fourth insulating layer 40 to form a conductive layer and then patterning the conductive layer. As described above, the upper electrode UE and the third upper capacitor electrode UCE3 may be filled in the contact holes CNT1-1 to CNT3-2 and connected to the first and second transistors TR1 and TR2.

According to the present invention, by arranging the capacitors respectively above and below the active layer, the minimum distance between the source and the drain of the transistor may be reduced. As a result, the number of the transistors disposed within a same area may increase, thereby being able to provide an electronic apparatus with improved resolution. In addition, since some of the capacitors are disposed below the active layer, it may be easy to secure the electrode areas of the capacitors, thereby being able to provide an electronic apparatus with improved reliability.

Although the above has been described with reference to embodiments of the inventive concept, those skilled in the art or those of ordinary skill in the art will understand that various modifications and changes can be made to the inventive concept within the scope that does not depart from the spirit and technical feature of the inventive concept set forth in the claims to be described later. Accordingly, the technical scope of the inventive concept should not be limited to the content described in the detailed description of the specification, but should be determined by the claims described hereinafter.

1. An electronic apparatus comprising:
a base layer;
a gate line disposed on the base layer and extending in a first direction;
a data line insulated from the gate line and extending in a second direction crossing the first direction; and
a pixel comprising a pixel driver connected to the gate line and the data line, and a light-emitting element disposed on the pixel driver and connected to the pixel driver,
wherein the light-emitting element comprises an anode, a cathode disposed on the anode, and a light-emitting layer disposed between the anode and the cathode, and
the pixel driver comprises a first transistor including a first semiconductor pattern and a first gate electrode overlapping the first semiconductor pattern, a second transistor including a second semiconductor pattern connected to the data line and spaced apart from the first semiconductor pattern and a second gate electrode overlapping the second semiconductor pattern, a first capacitor connected between the second transistor and the data line, and a second capacitor connected to the first transistor, and
wherein the first capacitor is disposed below the first semiconductor pattern, and the second capacitor is disposed above the first semiconductor pattern.

2. The electronic apparatus of claim 1, wherein the first capacitor comprises a first lower capacitor electrode and a second lower capacitor electrode disposed on the first lower capacitor electrode, and
an area occupied by each of the first and second lower capacitor electrodes is larger than an area occupied by the anode in a plan view.

3. The electronic apparatus of claim 2, wherein the first lower capacitor electrode has a shape integrated with the data line.

4. The electronic apparatus of claim 2, wherein the second lower capacitor electrode has a shape integrated with the data line.

5. The electronic apparatus of claim 2, wherein a ratio between the area occupied by each of the first and second lower capacitor electrodes and the area occupied by the anode is 1.4 or more.

6. The electronic apparatus of claim 1, further comprising:
a lower conductive pattern disposed between the first capacitor and the first transistor; and
a buffer layer disposed on the lower conductive pattern,
wherein the lower conductive pattern overlaps the first semiconductor pattern.

7. The electronic apparatus of claim 6, wherein a short-range surface roughness of the buffer layer is less than 10 nm, and
a long-range surface roughness of the buffer layer is less than 200 nm.

8. The electronic apparatus of claim 1, wherein the first transistor comprises a silicon semiconductor, and the second transistor comprises an oxide semiconductor.

9. The electronic apparatus of claim 1, wherein a spacing distance between the first semiconductor pattern and the anode in a third direction crossing the first direction and the second direction is 1.5 μm or less.

10. The electronic apparatus of claim 9, further comprising an upper electrode connecting the first capacitor to the second transistor,
wherein the upper electrode is disposed on the first capacitor and the second transistor.

11. The electronic apparatus of claim 10, wherein the upper electrode comprises a same material as at least one of electrodes of the second capacitor.

12. An electronic apparatus comprising:
a base layer;
a gate line disposed on the base layer and extending in a first direction;
a data line comprising a line portion insulated from the gate line and extending in a second direction crossing the first direction and a protruding portion protruding from the line portion; and
a pixel comprising a pixel driver connected to the gate line and the data line and a light-emitting element disposed on the pixel driver and connected to the pixel driver,
wherein the light-emitting element comprises an anode, a cathode disposed on the anode, and a light-emitting layer disposed between the anode and the cathode, and
the pixel driver comprises a first transistor including a first semiconductor pattern and a first gate electrode overlapping the first semiconductor pattern, a second transistor including a second semiconductor pattern connected to the data line and spaced apart from the first semiconductor pattern and a second gate electrode overlapping the second semiconductor pattern, and a capacitor electrode disposed below the first semiconductor pattern and overlapping the protruding portion of the data line in a plan view, and
wherein the protruding portion of the data line overlaps the anode in the plan view.

13. The electronic apparatus of claim 12, wherein an area occupied by each of the protruding portion and the capacitor electrode is larger than an area occupied by the anode.

14. The electronic apparatus of claim 12, wherein the capacitor electrode is disposed above the protruding portion.

15. The electronic apparatus of claim 12, wherein the capacitor electrode is disposed below the protruding portion.

16. The electronic apparatus of claim 12, further comprising:
a lower conductive pattern disposed between the capacitor electrode and the first transistor; and
a buffer layer disposed on the lower conductive pattern,
wherein the lower conductive pattern overlaps the first semiconductor pattern.

17. The electronic apparatus of claim 12, wherein the first transistor comprises a silicon semiconductor, and the second transistor comprises an oxide semiconductor.

18. The electronic apparatus of claim 12, further comprising:
an upper electrode connecting the capacitor electrode to the second transistor,
wherein the upper electrode is disposed on the capacitor electrode and the second transistor.

19. An electronic apparatus comprising:
a display module configured to display an image; and
a processor configured to provide image data to the display module,
wherein the display module comprises:
a base layer;
a gate line disposed on the base layer and extending in a first direction;
a data line insulated from the gate line and extending in a second direction crossing the first direction; and
a pixel comprising a pixel driver connected to the gate line and the data line and a light-emitting element disposed on the pixel driver and connected to the pixel driver,
wherein the light-emitting element comprises an anode, a cathode disposed on the anode, and a light-emitting layer disposed between the anode and the cathode, and
the pixel driver comprises a first transistor including a first semiconductor pattern and a first gate electrode overlapping the first semiconductor pattern, a second transistor including a second semiconductor pattern connected to the data line and spaced apart from the first semiconductor pattern and a second gate electrode overlapping the second semiconductor pattern, a first capacitor connected between the second transistor and the data line, and a second capacitor connected to the first transistor, and
wherein the first capacitor is disposed below the first semiconductor pattern, and the second capacitor is disposed above the first semiconductor pattern.

20. The electronic apparatus of claim 19, wherein
the first capacitor comprises a first lower capacitor electrode and a second lower capacitor electrode disposed on the first lower capacitor electrode, and
the area occupied by each of the first and second lower capacitor electrodes is larger than the area occupied by the anode in a plan view.
